(19) United States
(12) Patent Application Publication
(10) Pub. No.: US 2026/0136911 A1
(43) Pub. Date: May 14, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Cheng Ying LIN, HsinChu City (TW); Chih-Hong HWANG, New Taipei City (TW); Xiaodong WANG, Hsinchu City (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/941,455

(22) Filed: Nov. 8, 2024

(51) Int. Cl. H01L 23/528; H01L 21/768; H01L 21/8238; H01L 27/092; H01L 29/06; H01L 29/423; H01L 29/66; H01L 29/775; H01L 29/786

(52) U.S. Cl. CPC H10W 20/427; H10D 30/014; H10D 84/0172; H10D 84/038; H10D 84/85; H10W 20/01; H10D 30/43; H10D 30/6735; H10D 30/6757; H10D 62/121

(57) ABSTRACT

A method includes forming a plurality of first semiconductor channel layers stacked in a vertical direction over a substrate; forming a first gate strip surrounding each of the first semiconductor channel layers; forming a plurality of first source/drain regions on either side of each of the first semiconductor channel layers; forming a front-side source/drain contact over a front-side of a first one of the first source/drain regions; forming a first back-side source/drain contact over a back-side of a second one of the first source/drain regions, wherein a front-side of the second one of the first source/drain regions is free of a metal contact; forming a signal line over the front-side source/drain contact; forming a power supply voltage line over the first back-side source/drain contact.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 2A-5 illustrate layout diagrams of circuits in accordance with some embodiments of the present disclosure.

FIG. 1C illustrates an example of a semiconductor structure including nanostructure-FETs in a three-dimensional view in accordance with some embodiments of the present disclosure.

FIGS. 1D-1G illustrate schematic cross-sectional views obtained from reference cross-section A-A′, B-B′, C-C′, and D-D′ in FIG. 1A, respectively, in accordance with some embodiments of the present disclosure.

FIGS. 6-30D illustrate schematic views of intermediate stages in the formation of a semiconductor structure in accordance with some embodiments.

FIG. 31A is a schematic diagram of an electronic design automation (EDA) system in accordance with some embodiments of the present disclosure.

FIG. 31B is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, in a cell routing of the IC structure, Vdd and Vss power routing may occupy too many routing resources and therefore impact the cell scaling as well as the performance of the IC structure (e.g., RC delay or IR drop).

Therefore, the present disclosure in various embodiments provides a metal line routing method to improve the functional density and operation performance on the IC structure. Specifically, at least a part of power supply voltage lines (Vdd/Vss) and power conductive contacts can be moved to wafer back-side, so as to reduce the routing loading and improve the circuit density in a same chip area, which in turn simplifies the overall layout and reduces parasitic interactions. With fewer front-side source/drain contacts involved, the cut metal-like defined region (CMD) process can be streamlined. Additionally, the removal of source/drain contacts linked to power delivery can simplify the CPO process, allowing for easier and more consistent patterning across different semiconductor devices. In some embodiments, the gate via can be enlarged while no source/drain contact nearby, allowing for the enlargement of the critical dimension thereof, and thus optimizing the performance of the gate and reducing its electrical resistance.

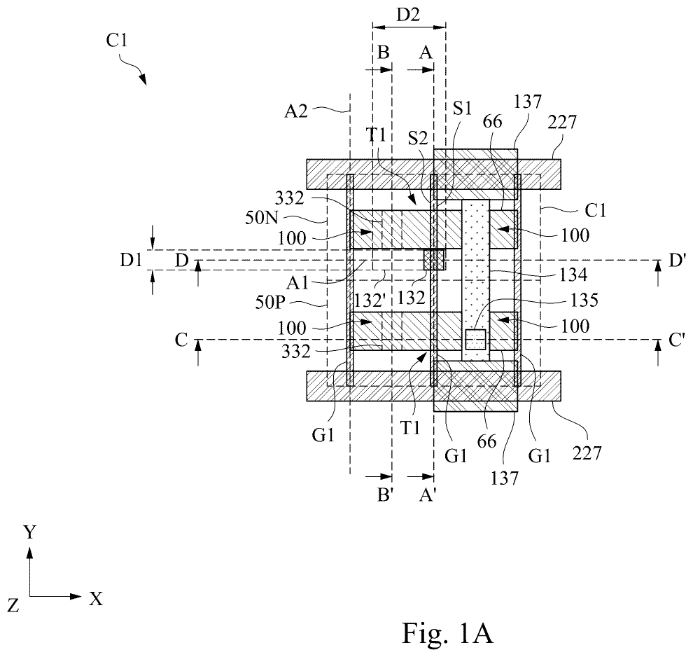

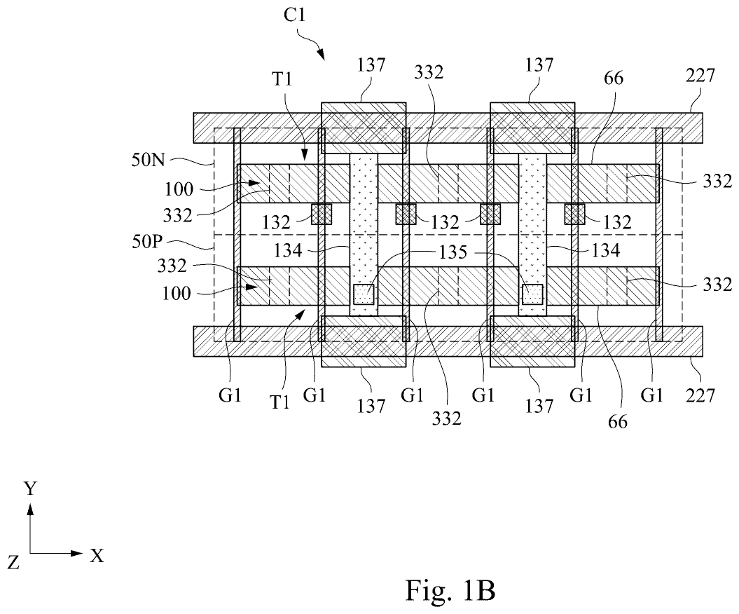

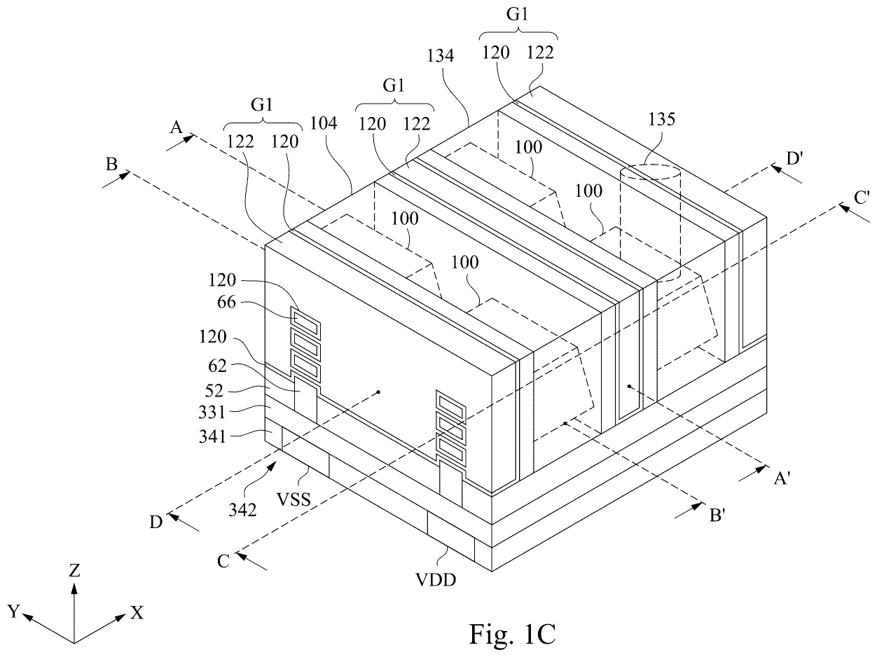

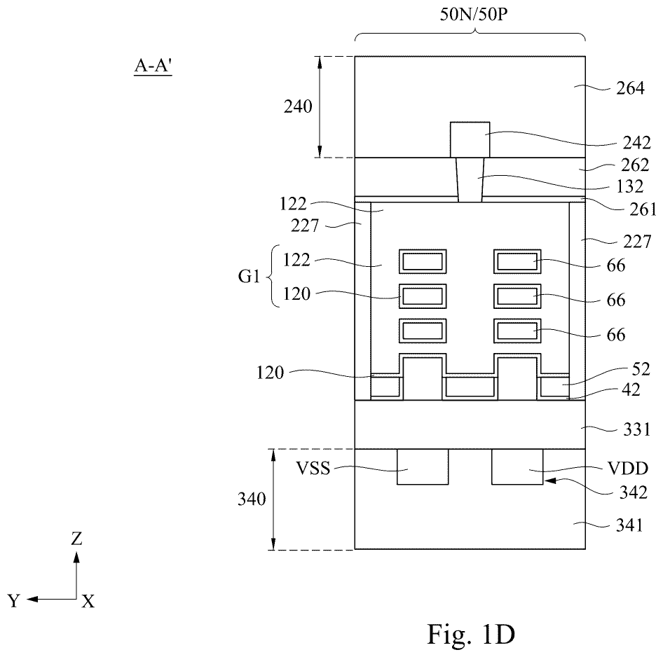

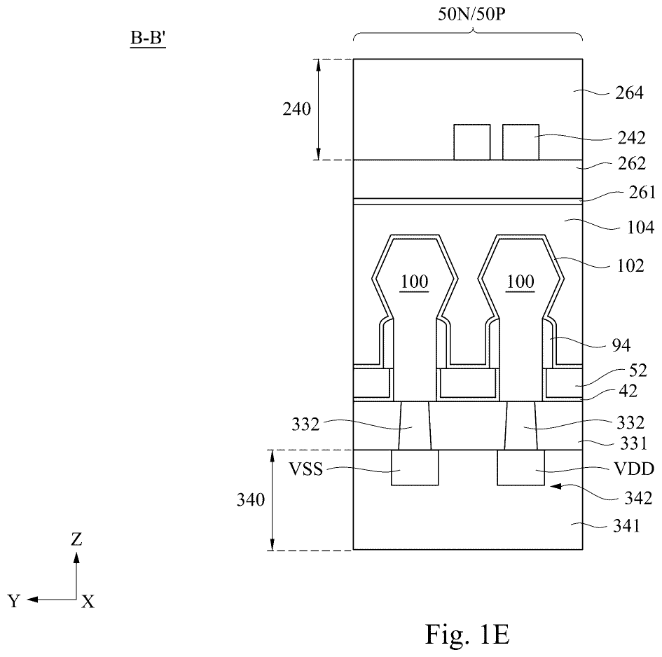

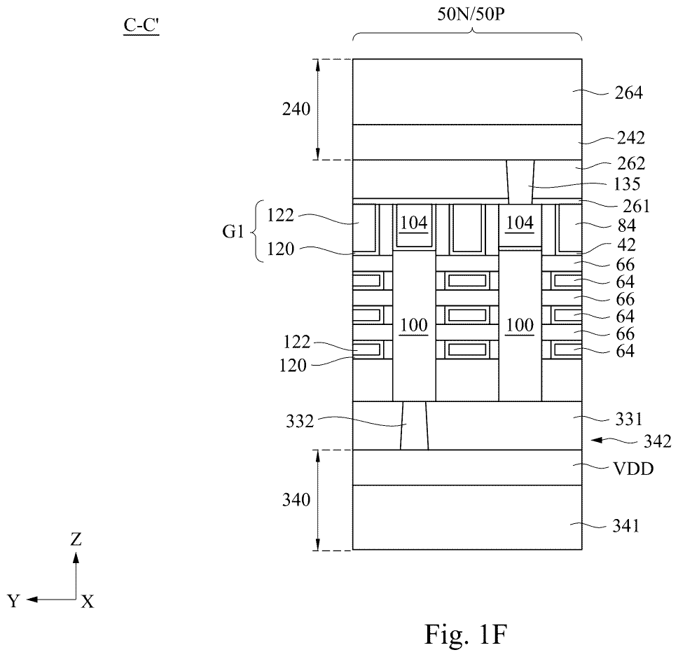

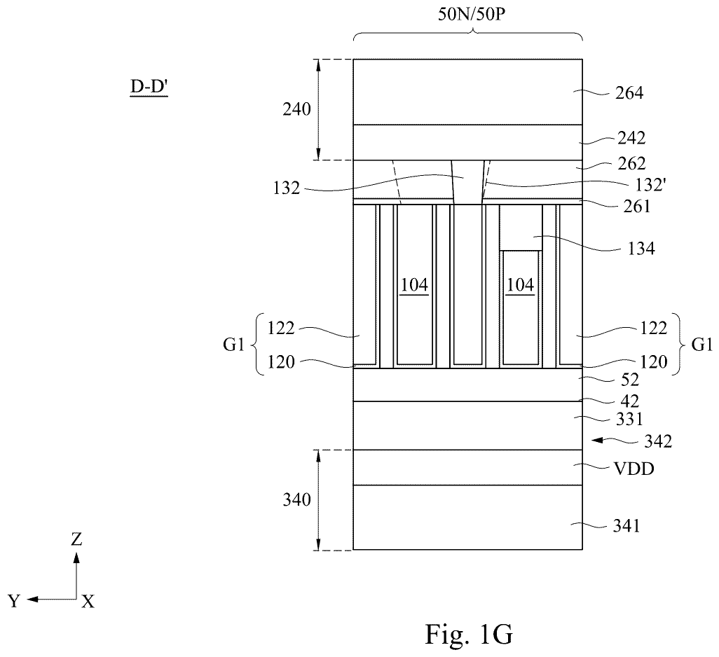

Reference is made to FIGS. 1A-1G. FIG. 1A illustrates a cell C1 of a circuit in accordance with some embodiments of the present disclosure. FIG. 1B illustrates an array of the cells C1 as shown in FIG. 1A in accordance with some embodiments of the present disclosure. FIG. 1C illustrates an example of nanostructure-FETs (e.g., nanowire FETs, nanosheet FETs, nano-FETs, or the like), gate-all-around (GAA) FETs, or the like) in a three-dimensional view in accordance with some embodiments of the present disclosure. FIGS. 1D-1G illustrate schematic cross-sectional views obtained from reference cross-section A-A′, B-B′, C-C′, and D-D′ in FIG. 1A, respectively. Cross-section A-A′ extends along a longitudinal axis A2 of a gate structure G1 (see FIG. 1A). Cross-section C-C′ is perpendicular to cross-section A-A′ and extends along a longitudinal axis of a fin 62 (see FIGS. 1C, 1D, and 1F) of a nanostructure-FET and in a direction of, for example, a current flow between the source/drain regions 100 (see FIGS. 1A, 1B, 1C, and 1F) of the nanostructure-FET. Cross-section D-D′ is parallel to cross-section B-B′ (e.g., is perpendicular to cross-section A-A′) and extends between adjacent fins 62 of the nanostructure-FETs and between the corresponding adjacent source/drain regions 100 of the nanostructure-FETs. Cross-section B-B′ is parallel to cross-section A-A′ and extends through source/drain regions 100 of the nanostructure-FETs. Subsequent figures refer to these reference cross-sections for clarity. Some features of the nanostructure-FETs may be simplified and/or omitted in FIGS. 1C-G for clarity.

As shown in FIGS. 1A and 1B, outer boundary of each of the cell C1 (e.g., logic circuit region) is illustrated using dashed lines. It should be noted that the configuration of the cell C1 is used as an illustration, and not to limit the disclosure. In some embodiments, the cell C1 can be a logic circuit. Each cell C1 can provide a circuit or portion thereof, exemplary functionality provided by the cells includes, but are not limited to NAND, NOR, AND, XOR, XNOR, SACN, inverter, Flip-Flop, latch, and/or other suitable logic or storage functions. By way of example but not limiting the present disclosure, the cell C1 may have an inverter circuit.

In some embodiments, the cell C1 may include a plurality of nanostructure-FETs in a first conductivity type device region 50N (see FIG. 1A) and a second conductivity type device region 50P (see FIG. 1A). By way of example but not limiting the present disclosure, the transistor in the first conductivity type device region 50N may be NMOSFET transistor, and the transistor in the second conductivity type device region 50P may be PMOSFET transistor. In some embodiments, the transistor in the first conductivity type device region 50N may be PMOSFET transistor, and the transistor in the second conductivity type device region 50P may be NMOSFET transistor.

In some embodiments, the transistors T1 in the first and second conductivity type device regions 50N and 50P can comprise nanostructures 66 (e.g., nanosheets, nanowires, or the like) over fins 62 that are over a back-side dielectric layer 331, with the nanostructures 66 being semiconductor features that act as channel regions for the nanostructure-FETs. The nanostructures 66 may include p-type nanostructures, n-type nanostructures, or a combination thereof. The nanostructures 66 can be stacked along the Z-direction (see FIG. 1C) and are wrapped by the gate electrode, and the Z-direction is perpendicular to the plane formed by the X-direction and Y-direction. In some embodiments, the nanostructure 66 can be interchangeable referred to as a channel layer, a channel pattern, an active region, or a semiconductive sheet. In some embodiments, the nanostructure 66 can have a length extending in the X-direction in a range from about 4 nm to about 12 nm, such as about 4, 5, 6, 7, 8, 9, 10, 11, or 12 nm.

In some embodiments, the cell C1 can include gate dielectric layers 120 (see FIGS. 1C, 1D, 1F, and 1G) can over top surfaces of the fins 62 and along top surfaces, sidewalls, and bottom surfaces of the nanostructures 66. Gate electrodes 122 (see FIGS. 1C, 1D, 1F, and 1G) are over the gate dielectric layers 120. The gate electrodes 122 can extend in the Y-direction and in parallel with each other. The gate dielectric layers 120 and gate electrodes 122 may be collectively be called gate structures G1. In some embodiments, the gate structure G1 can be interchangeable referred to as a gate stack, a gate pattern, a gate strip, a gate line, a gate layer, a metal gate, or a functional gate. In some embodiments, on the front side of the cell C1, the gate electrode 122 can be connected to an overlying level (e.g., front-side metallization layer 242) through a gate via 132. In some embodiments, the gate via 132 can be interchangeable referred to as a gate contact. Dielectric regions 227 (see FIGS. 1A, 1B, and 1D) can be formed on opposite ends of the gate structure G1. In some embodiments, each dielectric region 227 can be a gate-cut structure for the gate structure G1, and the gate-cut structure is formed by a cut metal gate (CMG) process. In some embodiments, the dielectric region 227 can be interchangeably referred to a gate end dielectric.

In some embodiments, source/drain regions 100 (e.g., epitaxial source/drain regions 100) can be disposed on the fins 62 at opposing sides of the gate dielectric layers 120 and the gate electrodes 122. Source/drain region(s) 100 may refer to a source or a drain, individually or collectively dependent upon the context. In some embodiments, the epitaxial source/drain region 100 can be interchangeable referred to as an epitaxial structure, a source/drain pattern, or a source/drain structure. An inter-layer dielectric (ILD) layer 104 is formed over the source/drain regions 100, and a contact etch stop layer (CESL) 102 can be formed between the ILD layer 104 and the epitaxial source/drain regions 100. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

In some embodiments, the source/drain regions 100 (or source nodes) (see FIGS. 1A, 1B, 1E, and 1F) which are of Vdd node and Vss node can be electrically coupled to underlying power supply voltage lines VSS and VDD (see FIGS. 1C-1G) through power supply voltage contacts 332. In some embodiments, the source/drain region 100 which is of Vdd node and Vss node can be interchangeably referred to as a power conductor connection, and the underlying power supply voltage contact 332 can be interchangeably referred to as a Vss/Vdd contact. The source/drain regions 100 (or drain nodes) (see FIGS. 1A-1C, 1F, and 1G) which are not of Vdd node and Vss node can be electrically coupled to a front-side metallization layer 242 through a source/drain contact 134 and a metal via 135. In some embodiments, the metal via 135 can be interchangeable referred to as a source/drain via or a source/drain contact.

In some embodiments, a front-side silicide layer 133 (see FIGS. 1E and 1F) can be formed between the source/drain contact 134 and the epitaxial source/drain region 100. By way of example but not limiting the present disclosure, the metal lines disposed at the M1 level on the front-side/back-side of the cell C1 may have lengthwise directions parallel to the X-direction (e.g., column direction).

In some embodiments, the source/drain contacts 134 can be formed in the CESL 102 and the ILD layer 104 and over the epitaxial source/drain regions 100 by, such as cut metal-like defined region (CMD) process. The CMD process can be a method to define and shape a CMD region 137 (e.g., a dielectric region including the CESL 102 and the ILD layer 104 between adjacent source/drain contacts 134) and the regions for metal interconnections (i.e., source/drain contacts 134) in the integrated circuits. That is, the CMD region 137 can be formed by the CMD process to isolate the metal contacts (e.g., adjacent source/drain contacts 134) over the source/drain regions 100. In some embodiments, the CMD region 137 can be interchangeable referred to as a dielectric region.

In some embodiments, the underlying power supply voltage line VDD can be interchangeably referred to as a Vdd line that is provided with positive a power supply voltage Vdd, and the underlying power supply voltage line VSS can be interchangeably referred to as a Vss line that is provided with power supply voltage Vss. In some embodiments, the cell C1 can be powered through the positive power supply node Vdd that has a positive power supply voltage. The cell C1 can be also connected to power supply voltage Vss, which may be an electrical ground. In some embodiments, the power supply voltage line VDD/VSS can be interchangeably referred to a power supply voltage landing pad or a power supply voltage landing line. In some embodiments, the lines can be interchangeably referred to metal layers, conductive lines, conductive layers, or conductors. In some embodiments, a back-side dielectric layer 331 (see FIGS. 1D-1G) can be formed between the source/drain regions 100 and the power supply voltage lines VSS and VDD, such that the source/drain regions 100 which are not of Vdd node and Vss node can be isolated from the underlying power supply voltage lines VSS and VDD.

Because there is no power delivery (i.e., M0 power rail such as power supply voltage lines VDD and VSS) on the front-side of the semiconductor structure in the cell C1, the source/drain contacts 134, which are originally associated with power delivery, can be eliminated. This elimination is because there are no connections needed between the power ground (i.e., power delivery lines like VDD and VSS) and the nanostructures 66 (i.e., channel region) on the front side. As a result, the bridge formed by the source/drain contacts 134 that connect these components can be eliminated. Therefore, the reduction in source/drain contacts 134 on the front-side of the semiconductor structure in cell C1 can lead to a decrease in the capacitance between the source/drain contacts 134 and the gate structure G1, which in turn helps to lower the electrical delay and power consumption, enhancing the overall performance and efficiency of the semiconductor device. By way of example but not limiting the present disclosure, in FIG. 1A, the illustration of the cell C1 can show that it does not have source/drain contacts 134 related to front-side power delivery, allowing for a reduction of about 50% in the number of front-side source/drain contacts compared to the cell C1 that includes front-side source/drain contacts dedicated to power delivery.

When the source/drain contact 134, dedicated to power delivery, can be removed from the front-side of the semiconductor structure in the cell C1, it frees up space on the semiconductor layout. This additional space can allow for adjustments of related components. For example, the gate via 132 can be expanded laterally, along the X-direction or longitudinal axis of fin 62, enabling the gate via 132 to have a larger critical dimension, which in turn reduces the contact resistance (Rc) of the gate via 132. As illustrated in FIGS. 1A and 1G, the gate via 132 can be replaced by a larger gate via 132′, which utilizes the extra space created by the removal of the source/drain contact 134, which in turn allows for facilitates better electrical performance. Additionally, from a top view as shown in FIG. 1A, a footprint of the gate via 132′ on a substrate can overlap with that of the power supply voltage contact 332. This overlap can be due to the increased dimensions of the gate via 132′, which in some embodiments, can be larger in the X-direction than both the dimensions of the source/drain contact 134 and the power supply voltage contact 332. This change in size and configuration can not only optimize the use of space within the semiconductor structure but also enhance the functionality and efficiency of the connections.

As shown in FIG. 1A, the gate via 132′ can have a longitudinal axis A1 extending in a direction perpendicular to a lengthwise direction of the gate structure G1. Specifically, the gate via 132′ can have a first dimension D1 extending along a lengthwise direction (e.g., Y-direction) of the gate structure G1, and a second dimension D2 extending along a direction (e.g., X-direction) perpendicular to the lengthwise direction of the gate structure G1, and the second dimension D2 can be greater than the first dimension D1. In some embodiments, the second dimension D2 can be greater than twice of the first dimension D1. By way of example but not limiting the present disclosure, the second dimension D2 can be about twice, 3, 4, 5, 6, 7, 8, 9, or 10 times of the first dimension D1. In some embodiments, from the top view, the gate structure G1 can have a first longitudinal side S1 and a second longitudinal side S2 between the first longitudinal side and the power supply voltage contacts 332, and the second dimension D2 can extend across the second longitudinal side S1 of the gate structure G1. As shown in FIGS. 1A and 1G, the gate via 132′ can extend across the gate spacer 92. The gate via 132′ can be asymmetric based on a longitudinal axis A of the gate structure G1. In some embodiments, the gate via 132′ can have a greater dimension than the metal vias 135 in a direction perpendicular to a lengthwise direction of the gate structure G1. In some embodiments, an area of a top surface of the gate via 132′ can be greater than an area of a top surface of the metal vias 135. In some embodiments, the gate via 132′ can overlap with the nanostructures 66.

Furthermore, when the source/drain contact 134, dedicated to power delivery, can be removed from the front-side of the semiconductor structure in cell C1, this adjustment can alter the usage and design of the CMD region 137. For example, the CMD region 137 can be used for forming source/drain contacts 134 related to signal interconnection, allowing for more targeted adjustments to the profile, size, and position of the CMD region 137, simplifying its patterning process. By way of example but not limiting the present disclosure, without the constraints imposed by integrating power delivery on the front-side of the semiconductor structure, the CMD region 137 can be positioned further from the nanostructures 66 along the Y-direction. This relocation can provide the flexibility to extend the length of the source/drain contact 134 in the Y-direction, thereby increasing its top surface area, and thus the larger top surface area of the source/drain contact 134 subsequently can provide a more process window for forming the metal via 135. Additionally, the larger contact area can not only facilitate easier and more reliable connections via the metal via 135 but also improve the electrical performance by decreasing contact resistance and enhancing signal integrity.

The configuration of the source/drain contact 134 in the cell C1 of the semiconductor structure can optimize to not directly connect to the power supply voltage lines, which in turn simplifies the configuration of the source/drain contact 134 on the front-side of the semiconductor structure, dedicating it to signal interconnection. By streamlining the role of the source/drain contact 134 to focus on signal interconnection, this arrangement can eliminate the complexity associated with dual-function contacts that manage both power delivery and signal transmission. Moreover, this simplified configuration can help to avoid potential issues such as the floating of the source/drain contact 134. “Floating” in this context refers to an electrical state where the contact is not securely connected to a definite voltage level (power or ground), which can lead to unstable behavior in the device's operation. By ensuring that the source/drain contacts are involved in signal interconnection, their electrical behavior can become more predictable and stable, enhancing the overall reliability and performance of the semiconductor device.

Reference is made to FIG. 1B. FIG. 1B illustrates a layout diagram of a cell array, including multiple cells C1, according to some embodiments of the present disclosure. In some embodiments, the cell array depicted in FIG. 1B may illustrate a series connection of multiple cells C1, as shown individually in FIG. 1A. The present disclosure may repeat reference numerals and/or letters in the various examples. This repetition is for the purpose of simplicity and clarity and does not in itself dictate a relationship between the various embodiments and/or configurations discussed.

The adjustments made to the configuration of the source/drain contact 134 in FIG. 1B can lead to a reduced capacitance between the source/drain contacts 134 and the gate structures G1. This reduction in capacitance can simplify the design and fabrication processes across multiple cells C1, as illustrated in FIG. 1B. Due to the reduced need to manage capacitance variations, it is no longer to customize the sizes of dielectric regions 227 to adjust for capacitance effects between the source/drain contact 134 and different gate structures G1 across the cells C1 in the cell array. As a result, the sizes of the dielectric regions 227 can be standardized across different gate structures G1, allowing for a simplification of the CPO patterning and processing. For example, the inner edges of the dielectric regions 227 across different gate structures G1 can be made collinear form the top view, meaning they can align in a straight line, ensuring consistency in the electrical properties across the cells C1 in the cell array. In other words, a distance between a first dielectric region 227 and the nanostructures 66 can be substantially equal to a distance between a second dielectric region 227 and the nanostructures 66. By way of example but not limiting the present disclosure, in FIG. 1B, the illustration of the cell array can show that it does not have source/drain contacts 134 related to front-side power delivery, allowing for a reduction of about 60% in the number of front-side source/drain contacts compared to the cell array that includes front-side source/drain contacts dedicated to power delivery.

As shown in FIG. 1C-1E and 1G, a dielectric liner 42 and a hard mask 52 can be disposed between adjacent fins 62, which may protrude above and from between neighboring dielectric liner 42 and hard mask 52. The nanostructures 66 are disposed over and between adjacent the dielectric liner 42 and the hard mask 52. In some embodiments, the dielectric liner 42 and the hard mask 52 can interchangeable referred to as shallow trench isolation (STI) structure.

In FIGS. 1F and 1G, gate spacers 92 can be formed on sidewalls of the gate structure G1 to separate the epitaxial source/drain regions 100 from the gate structure G1, and inner spacers 98 can be formed to separate the epitaxial source/drain regions 100 from the nanostructures 66 by an appropriate lateral distance such that the epitaxial source/drain regions 100 do not short out with the gate structures G1. In FIG. 1E, fin spacers 94 can be formed to cover portions of the sidewalls of the nanostructures 66, further blocking the epitaxial growth.

As shown in FIGS. 1D-1G, an ILD layer 262 can be deposited over the CESL 102 and the ILD layer 104. The metal via 135 (see FIGS. 1F and 1G) can be formed in the ILD layer 262 and land on the source/drain contact 134, and the gate via 132 (see FIGS. 1D and 1G) can be formed to pass through the ILD layer 262 and land on the gate structure G1. A front-side interconnect structure 240 can be formed over the front-side gate via 132 and metal vias 135. The front-side interconnect structure 240 can include a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure 240 may include front-side inter-metal dielectric (IMD) layer 264 and at least one front-side metallization layer 242 formed in the IMD layer 264. In some embodiments, the front-side metallization layer 242 may include, such as a bit line, a complementary bit line, and/or a word line. In some embodiments, the front-side metallization layer 242 can be interchangeable referred to as a metal line, a metal layer, a metal pad, or a line pattern.

In some embodiments, a back-side interconnect structure 340 can be formed over the back-side dielectric layer 331. The back-side interconnect structure 340 can include a back-side IMD layer 341 and a plurality of metallization layers 342 with a plurality of metallization vias or interconnects formed in the back-side IMD layer 341. Other embodiments may contain more or fewer metallization layers and corresponding more or fewer number of vias. The metal line illustrated here just for an example, and the metal line may be otherwise oriented (rotated 90 degrees or at other orientations). The metallization layers 342 may include the power supply voltage lines VSS and VDD formed in a first back-side metallization layer, and include other power supply voltage lines formed in a second back-side metallization layer over the first back-side metallization layer. In some embodiments, the front-side metallization layer 342 can be interchangeable referred to as a metal line, a metal layer, a metal pad, or a line pattern.

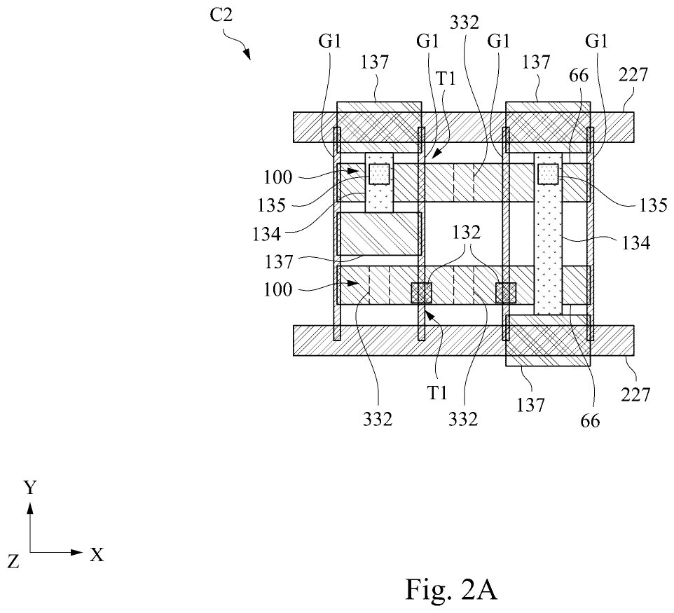

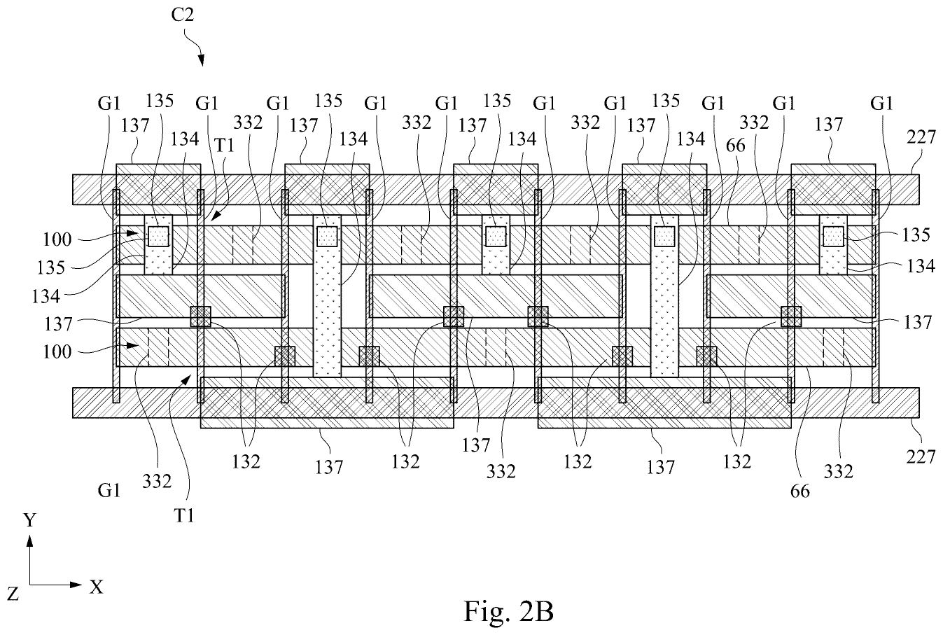

Reference is made to FIGS. 2A and 2B. FIG. 2A illustrates a cell C2 of a circuit in accordance with some embodiments of the present disclosure. FIG. 2B illustrates a layout diagram of a cell array, including multiple cells C2, according to some embodiments of the present disclosure. In some embodiments, the cell array depicted in FIG. 2B may illustrate a series connection of multiple cells C2, as shown individually in FIG. 2A. FIGS. 2A and 2B show embodiments with different layout profiles than the those in FIGS. 1A and 1B. In addition, the present disclosure may repeat reference numerals and/or letters in the various examples. This repetition is for the purpose of simplicity and clarity and does not in itself dictate a relationship between the various embodiments and/or configurations discussed.

The difference between FIG. 2A and FIG. 1A may lie in the types of circuits illustrated within the cells. Specifically, FIG. 2A may illustrate the cell C2 configured as a NAND circuit, while FIG. 1A may illustrate the cell C1 configured as an inverter circuit, showing the versatility in the design and application of different logic functions within similar semiconductor layouts, allowing for the adaptation of the semiconductor structure to meet various operational requirements. In some embodiments, as shown in FIG. 2A, the illustration of the cell C2 can show that it does not have source/drain contacts 134 related to front-side power delivery, allowing for a reduction of about 50% in the number of front-side source/drain contacts compared to the cell C2 that includes front-side source/drain contacts dedicated to power delivery. In some embodiments, as shown FIG. 2B, the illustration of the cell array can show that it does not have source/drain contacts 134 related to front-side power delivery, allowing for a reduction of about 61% in the number of front-side source/drain contacts compared to the cell array that includes front-side source/drain contacts dedicated to power delivery.

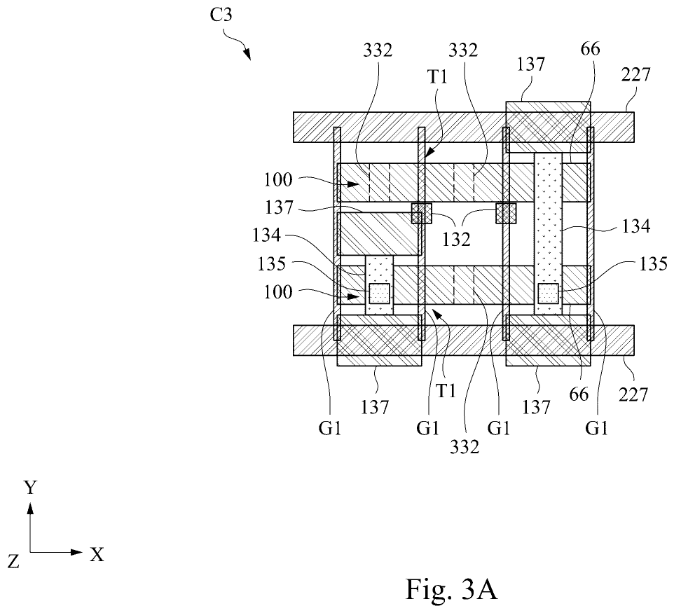

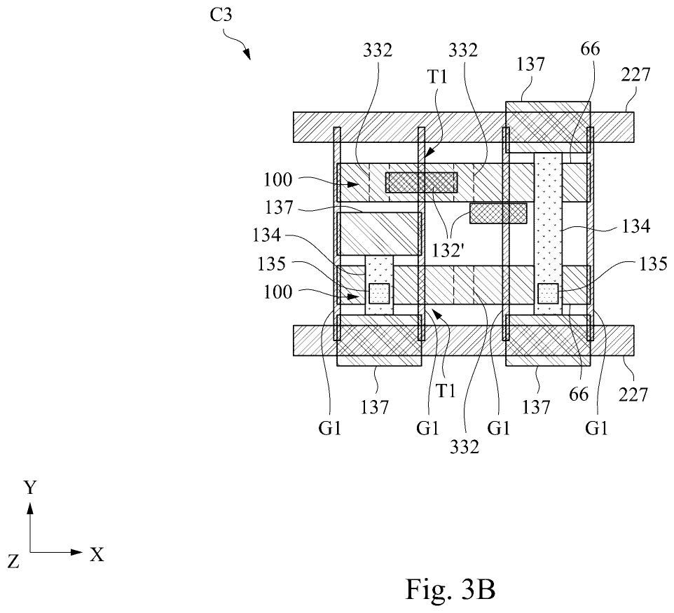

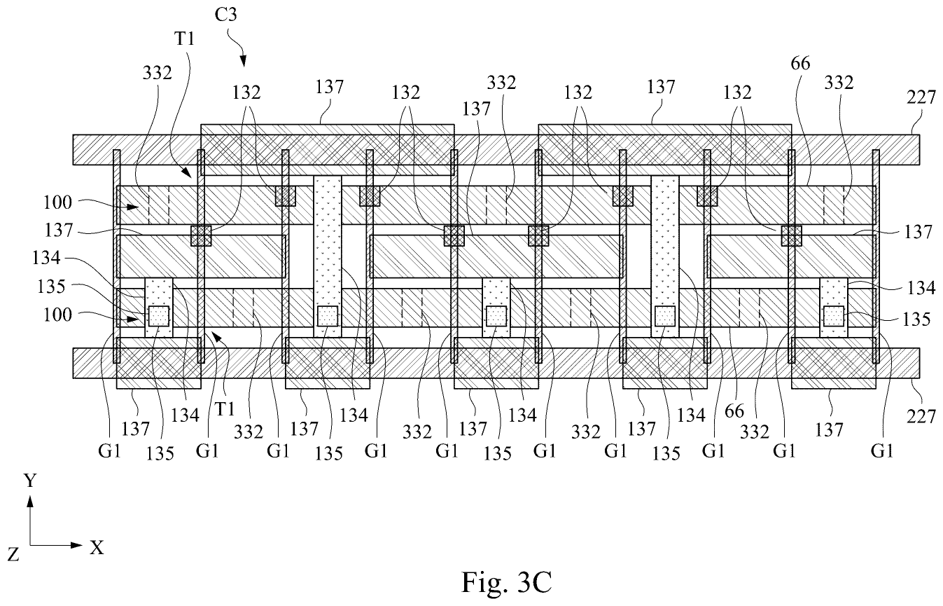

Reference is made to FIGS. 3A-3C. FIGS. 3A and 3B illustrate a cell C3 of a circuit in accordance with some embodiments of the present disclosure, in which gate via in FIG. 3B (i.e., gate via 132′) has a different top view profile than that shown in FIG. 3A. FIG. 3C illustrates a layout diagram of a cell array, including multiple cells C3, according to some embodiments of the present disclosure. In some embodiments, the cell array depicted in FIG. 3C may illustrate a series connection of multiple cells C3, as shown individually in FIG. 3A and/or FIG. 3B. FIGS. 3A-3C show embodiments with different layout profiles than the those in FIGS. 1A and 1B. In addition, the present disclosure may repeat reference numerals and/or letters in the various examples. This repetition is for the purpose of simplicity and clarity and does not in itself dictate a relationship between the various embodiments and/or configurations discussed.

The difference between FIG. 3A and FIG. 1A may lie in the types of circuits illustrated within the cells. Specifically, FIG. 3A may illustrate the cell C3 configured as a NOR circuit, while FIG. 1A may illustrate the cell C1 configured as an inverter circuit, showing the versatility in the design and application of different logic functions within similar semiconductor layouts, allowing for the adaptation of the semiconductor structure to meet various operational requirements. In some embodiments, as shown in FIG. 3A, the illustration of the cell C3 can show that it does not have source/drain contacts 134 related to front-side power delivery, allowing for a reduction of about 50% in the number of front-side source/drain contacts compared to the cell C2 that includes front-side source/drain contacts dedicated to power delivery. In some embodiments, as shown FIG. 3B, the illustration of the cell array can show that it does not have source/drain contacts 134 related to front-side power delivery, allowing for a reduction of about 61% in the number of front-side source/drain contacts compared to the cell array that includes front-side source/drain contacts dedicated to power delivery.

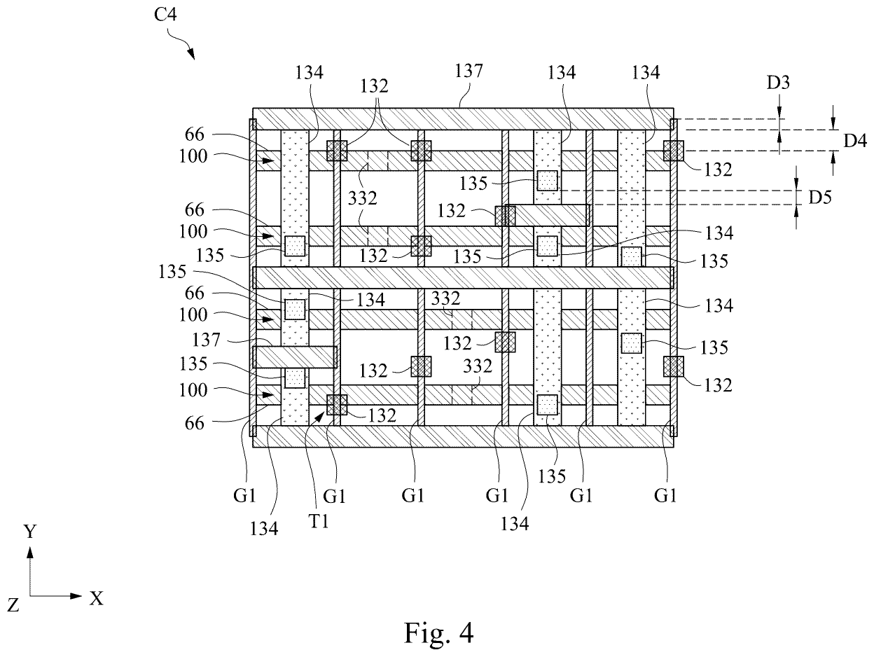

Reference is made to FIG. 4. FIG. 4 illustrates a cell array including multiple cells C4 of a circuit in accordance with some embodiments of the present disclosure. FIG. 4 shows an embodiment with a different layout profile than that in FIG. 1B. In addition, the present disclosure may repeat reference numerals and/or letters in the various examples. The difference between FIG. 4 and FIG. 1B may lie in the types of circuits illustrated within the cells. This repetition is for the purpose of simplicity and clarity and does not in itself dictate a relationship between the various embodiments and/or configurations discussed.

Because there is no power delivery (i.e., M0 power rail such as power supply voltage lines VDD and VSS) on the front-side of the semiconductor structure in the cell C4, the source/drain contacts 134, which are originally associated with power delivery, can be eliminated. This elimination is because there are no connections needed between the power ground (i.e., power delivery lines like VDD and VSS) and the channel region on the front side. As a result, the bridge formed by the source/drain contacts 134 that connect these components can be eliminated. Therefore, the reduction in source/drain contacts 134 on the front-side of the semiconductor structure in cell C4 can lead to a decrease in the capacitance between the source/drain contacts 134 and the gate structure G1, which in turn helps to lower the electrical delay and power consumption, enhancing the overall performance and efficiency of the semiconductor device.

Furthermore, when the source/drain contact 134, dedicated to power delivery, can be removed from the front-side of the semiconductor structure in cell C4, this adjustment can alter the usage and design of the CMD region 137. For example, the CMD region 137 can be used for forming source/drain contacts 134 related to signal interconnection, allowing for more targeted adjustments to the profile, size, and position of the CMD region 137, simplifying its patterning process. By way of example but not limiting the present disclosure, without the constraints imposed by integrating power delivery on the front-side of the semiconductor structure, the CMD region 137 can be positioned further from the nanostructures 66 along the Y-direction, creating a deliberate space designated as a distance D4. The distance D4 can range from about 3 to 7 nanometers (nm), such as about 3, 4, 5, 6, or 7 nm. On the other hand, as shown in FIG. 1A, in a lengthwise direction of the gate structure G1, the distance D4 between a longitudinal end of the source/drain contact 134 and the nanostructures 66 can be greater than a distance D3 between the longitudinal end of the source/drain contact 134 and a longitudinal end of the gate structure G1.

In some embodiments, the relocation can provide the flexibility to extend the length of the source/drain contact 134 in the Y-direction, thereby increasing its top surface area, and thus the larger top surface area of the source/drain contact 134 subsequently can provide a more process window for forming the metal via 135. Additionally, the larger contact area can not only facilitate easier and more reliable connections via the metal via 135 but also improve the electrical performance by decreasing contact resistance and enhancing signal integrity. Specifically, the metal via 135 can be positioned within the boundaries of the enlarged source/drain contact 134, and can be spaced apart from the nearest edge of the source/drain contact 134 that extends in the X-direction. This spacing, designated as a distance D5, can range between about 4 to 6 nanometers (nm), such as about 4, 5, or 6 nm.

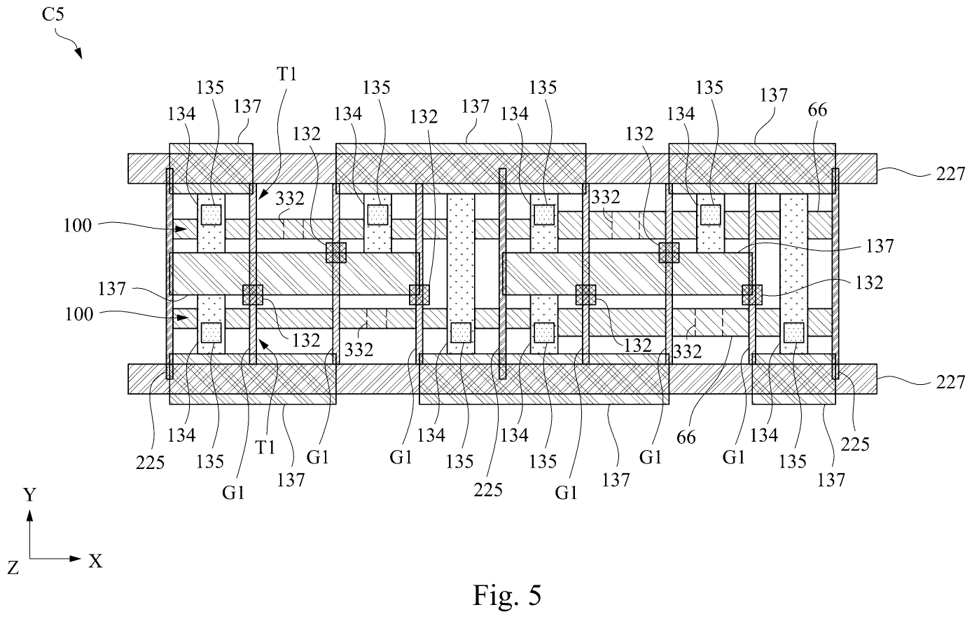

Reference is made to FIG. 5. FIG. 5 illustrates a cell array including multiple cells C5 of a circuit in accordance with some embodiments of the present disclosure. FIG. 5 shows an embodiment with a different layout profile than that in FIG. 1B. The difference between FIG. 5 and FIG. 1B may lie in the types of circuits illustrated within the cells. The present disclosure may repeat reference numerals and/or letters in the various examples. This repetition is for the purpose of simplicity and clarity and does not in itself dictate a relationship between the various embodiments and/or configurations discussed.

Because there is no power delivery (i.e., M0 power rail such as power supply voltage lines VDD and VSS) on the front-side of the semiconductor structure in the cell C5, the source/drain contacts 134, which are originally associated with power delivery, can be eliminated. This elimination is because there are no connections needed between the power ground (i.e., power delivery lines like VDD and VSS) and the channel region on the front side. As a result, the bridge formed by the source/drain contacts 134 that connect these components can be eliminated. Therefore, the reduction in source/drain contacts 134 on the front-side of the semiconductor structure in cell C1 can lead to a decrease in the capacitance between the source/drain contacts 134 and the gate structure G1, which in turn helps to lower the electrical delay and power consumption, enhancing the overall performance and efficiency of the semiconductor device.

Due to the reduced need to manage capacitance variations, it is no longer to customize the sizes of dielectric regions 227 to adjust for capacitance effects between the source/drain contact 134 and different gate structures G1 across the cells C5 in the cell array. As a result, the sizes of the dielectric regions 227 can be standardized across different gate structures G1, allowing for a simplification of the CPO patterning and processing. For example, the inner edges of the dielectric regions 227 across different gate structures G1 can be made collinear form the top view, meaning they can align in a straight line, ensuring consistency in the electrical properties across the cells C1 in the cell array. By way of example but not limiting the present disclosure, in FIG. 5, the illustration of the cell array can show that it does not have source/drain contacts 134 related to front-side power delivery, allowing for a reduction of about 50% in the number of front-side source/drain contacts compared to the cell array that includes front-side source/drain contacts dedicated to power delivery.

In some embodiments, due to adjustments in the configuration of dielectric regions 227, the overlapping area between the source/drain contact 134 and the gate structure G1 in the X-direction can be reduced, contributing to a decrease in the capacitance between the source/drain contacts 134 and the gate structures G1. Specifically, in some embodiments, this adjustment can lead to a reduction in the overlapping area by at least about 10%, such as about 10, 15, 20, 25, 30, 35, or 40%, which in turn minimizes the capacitive coupling between the source/drain contacts 134 and the gate structures G1, enhancing the overall electrical performance and efficiency of the semiconductor device.

In some embodiments, semiconductor structure shown in FIG. 5 may include dielectric-base gates 225 extending in the Y-direction. The gate structures G1 can be arranged between adjacent two of the dielectric-base gates 225. In other words, the gate electrodes 220 extend in parallel with each other, and the dielectric-base gates 225 extend in parallel with a lengthwise direction of the gate electrodes 220. The transistors T1 can be surrounded by the dielectric-base gates 225. The dielectric-base gates 225 can be formed in the boundary of the circuit region. Moreover, one of the dielectric-base gates 225 between the circuit regions can be shared by the second logic circuit regions. The material of the dielectric-base gates 225 is different from that of the gate electrodes 122. In some embodiments, the dielectric-base gates 225 can be interchangeably referred to dummy gates, dummy gate pattern, dummy gate strip, isolation structures/dielectric gates serving as circuit boundaries.

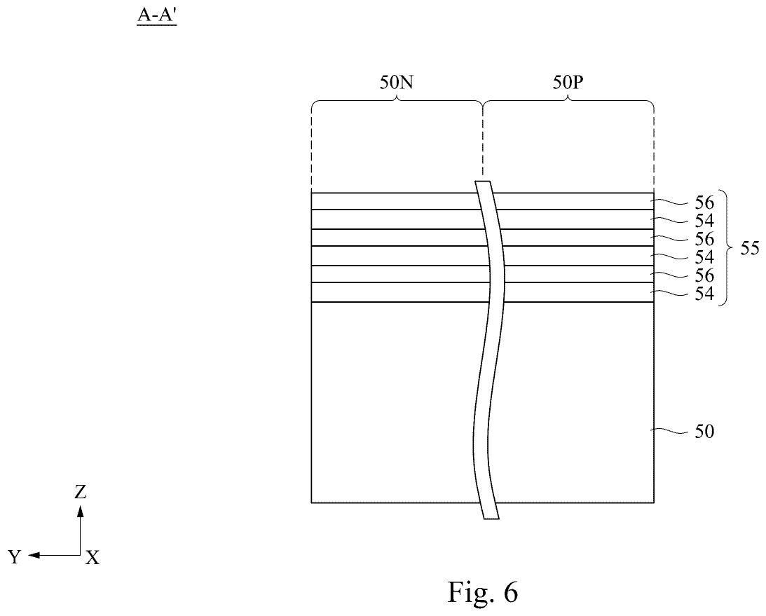

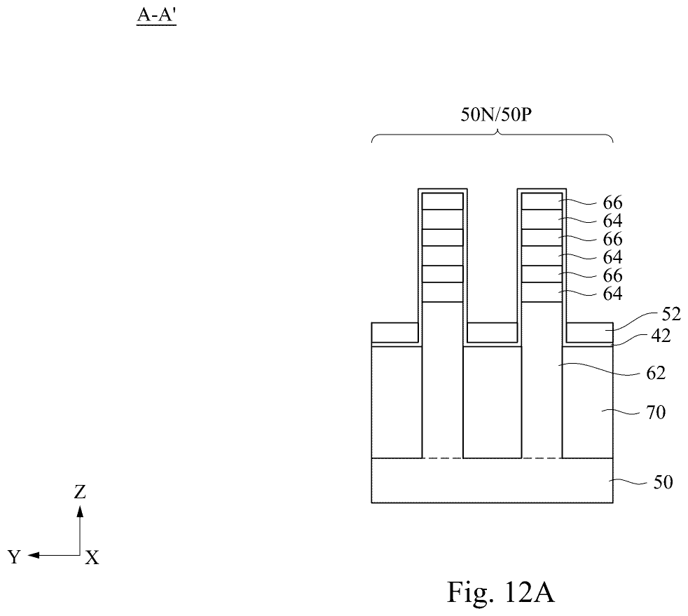

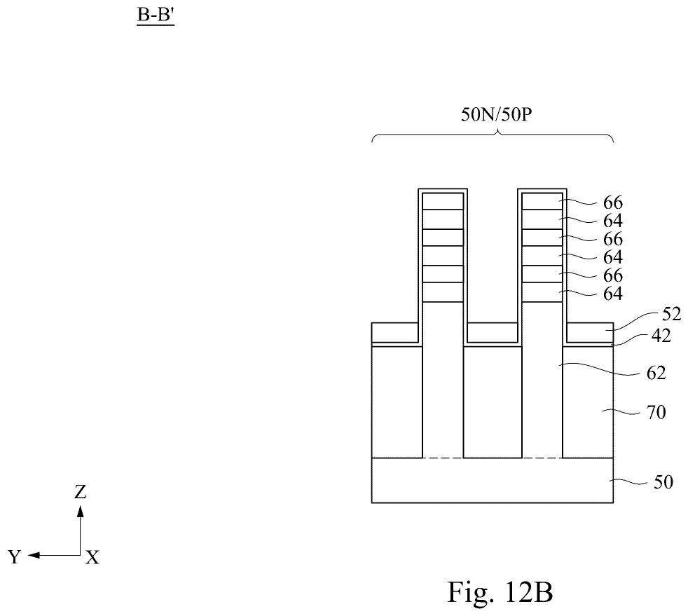

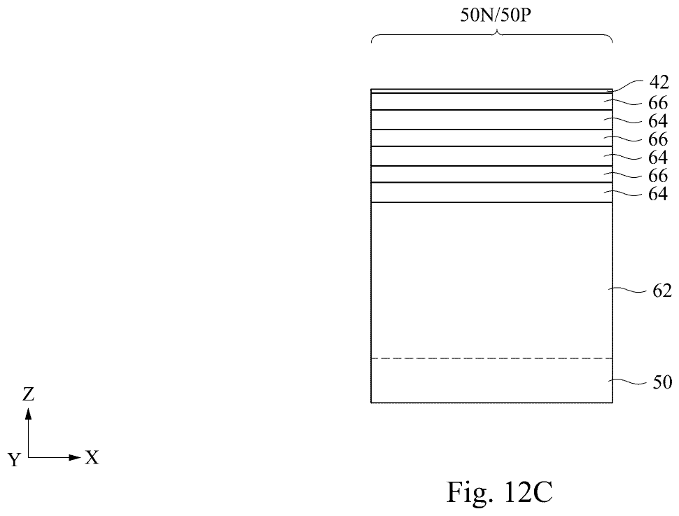

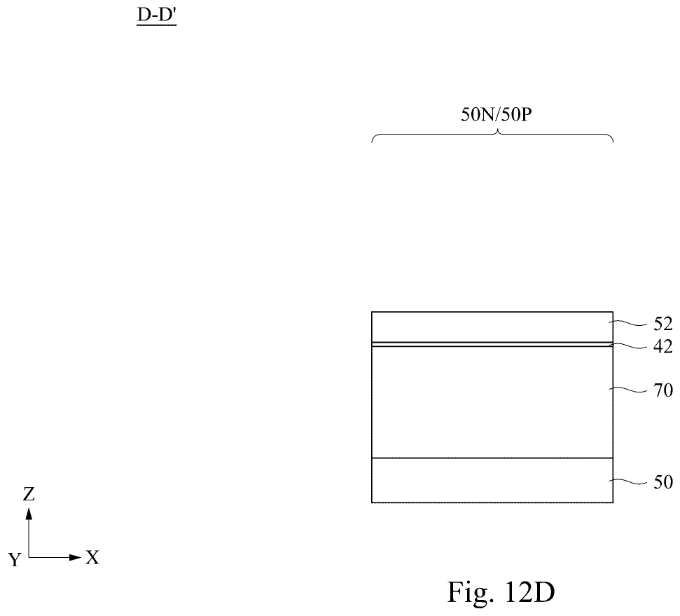

Reference is made to FIGS. 6-30D. FIGS. 6-30D illustrate schematic views of intermediate stages in the formation of a semiconductor structure in accordance with some embodiments. FIGS. 6-12A, 13A, 14A, 15A, 16A, 17A, 18A, 19A, 20A, 21A, 22A, 23A, 24A, 25A, 26A, 27A, 28A, 29A, and 30A illustrate cross-sectional views of intermediate stages obtained from the reference cross-section A-A′ in the formation of the semiconductor structure of FIG. 1A in accordance with some embodiments. FIGS. 12B, 13B, 14B, 15B, 20B, 21B, 22B, 23B, 24B, 25B, 26B, 27B, 28B, 29B, and 30B illustrate cross-sectional views of intermediate stages obtained from the reference cross-section B-B′ in the formation of the semiconductor structure in accordance with some embodiments. FIGS. 12C, 13C, 14C, 15C, 16B, 17B, 18B, 19B, 20C, 21C, 22C, 23C, 24C, 25C, 26C, 27C, 28C, 29C, and 30C illustrate cross-sectional views of intermediate stages obtained from the reference cross-section C-C′ in the formation of the semiconductor structure in accordance with some embodiments. FIGS. 12D, 13D, 14D, 15D, 20D, 21D, 22D, 23D, 24D, 25D, 26D, 27D, 28D, 29D, and 30D illustrate cross-sectional views of intermediate stages obtained from the reference cross-section D-D′ in the formation of the semiconductor structure in accordance with some embodiments.

As with the other method embodiments and exemplary devices discussed herein, it is understood that parts of the semiconductor structure may be fabricated by a CMOS technology process flow, and thus some processes are only briefly described herein. Further, the exemplary semiconductor structure may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary semiconductor structure includes a plurality of semiconductor devices (e.g., transistors), including PFETs, NFETs, etc., which may be interconnected. It is understood that additional operations can be provided before, during, and after the processes shown by FIGS. 6-30D, and some of the operations described below can be replaced or eliminated, for additional embodiments of the method. The order of the operations/processes may be interchangeable.

Reference is made to FIG. 6. A substrate 50 can be provided, in accordance with some embodiments. The substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. An SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have a first conductivity type device region 50N and a second conductivity type device region 50P. The first conductivity type device region 50N can be for forming n-type devices, such as NMOS transistors, e.g., n-type nanostructure-FETs, and the second conductivity type device region 50P can be for forming p-type devices, such as PMOS transistors, e.g., p-type nanostructure-FETs. The first conductivity type device region 50N may (or may not) be physically separated (not separately illustrated) from the second conductivity type device region 50P, and any number of device features (e.g., other active devices, doped regions, isolation structures, etc.) may be disposed between the first conductivity type device region 50N and the second conductivity type device region 50P. Although one first conductivity type device region 50N and one second conductivity type device region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 6, a multi-layer stack 55 can be formed over the substrate 50, in accordance with some embodiments. The multi-layer stack 55 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the first conductivity type device region 50N and the second conductivity type device region 50P. In such embodiments, the channel regions in both the first conductivity type device region 50N and the second conductivity type device region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 are patterned to form channel regions for nanostructure-FETs in one region (e.g., the second conductivity type device region 50P), and the second semiconductor layers 56 are patterned to form channel regions for nanostructure-FETs in another region (e.g., the first conductivity type device region 50N). The first semiconductor material of the first semiconductor layers 54 may be a material suitable for p-type devices, such as silicon germanium (e.g., SixGe 1-x, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the first conductivity type device region 50N, and the second semiconductor layers 56 may be removed without significantly removing the first semiconductor layers 54 in the second conductivity type device region 50P.

The multi-layer stack 55 can be illustrated as including three of the first semiconductor layers 54 and three of the second semiconductor layers 56. It should be appreciated that the multi-layer stack 55 may include any number of the first semiconductor layers 54 and the second semiconductor layers 56. Each of the layers of the multi-layer stack 55 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 55 are formed to be thinner than other layers of the multi-layer stack 55. For example, in other embodiments, the bottom-most second semiconductor layer 56 (e.g., the second semiconductor layer 56 closest to the substrate 50) may be thinner than overlying second semiconductor layers 56 to improve short channel control in the resulting nanostructure-FETs. Other combinations or variations of layer thicknesses are possible.

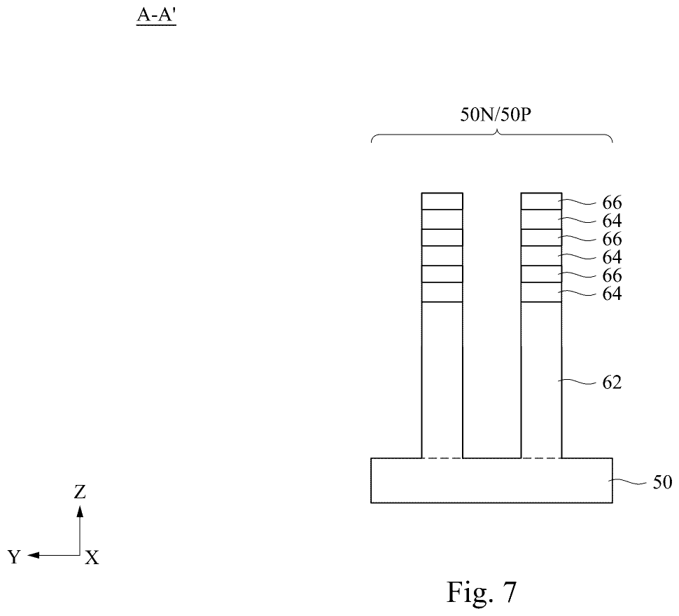

Reference is made to FIG. 7. Fins 62 can be formed in the substrate 50, and first nanostructures 64 and second nanostructures 66 can be formed in the multi-layer stack 55, in accordance with some embodiments. The first nanostructures 64 and the second nanostructures 66 may be collectively referred to as the nanostructures 64/66 herein. In some cases, the nanostructures 64/66 over a fin 62 may be considered a nanostructure stack or the like. FIG. 7 may be in either of the first conductivity type device region 50N or the second conductivity type device region 50P of the substrate 50 unless specifically discussed.

In some embodiments, the nanostructures 64/66 and the fins 62 may be formed in the multi-layer stack 55 and the substrate 50, respectively, by etching trenches in the multi-layer stack 55 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 55 may further define first nanostructures 64 from the first semiconductor layers 54 and define second nanostructures 66 from the second semiconductor layers 56.

The fins 62 and the nanostructures 64/66 may be patterned using any suitable methods. For example, the fins 62 and the nanostructures 64/66 may be patterned using one or more photolithography processes, including double-patterning or multi-patterning processes. Double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66. Other patterning techniques are possible.

The fins 62 are illustrated as having substantially equal widths in both the first conductivity type device region 50N and the second conductivity type device region 50P. In other embodiments, a width of the fins 62 in the first conductivity type device region 50N may be greater or less than a width of the fins 62 in the second conductivity type device region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

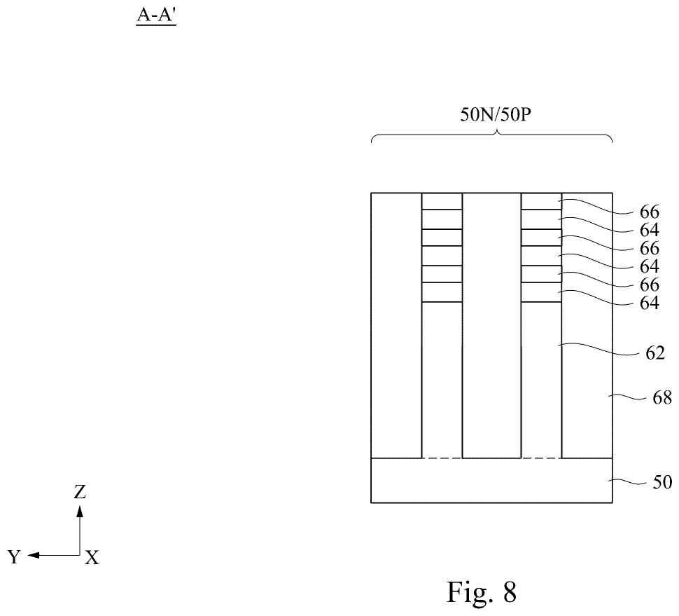

Reference is made to FIG. 8. An insulation material 68 can be formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 can be formed. Although the insulation material 68 can be illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials, may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, a combination thereof, or the like may be utilized. The planarization process may expose the nanostructures 64/66 such that top surfaces of the nanostructures 64/66 and the insulation material 68 are substantially level or coplanar after the planarization process is complete.

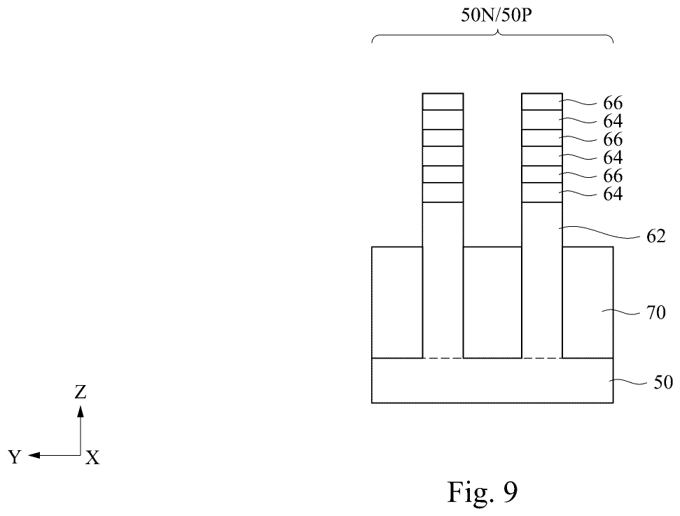

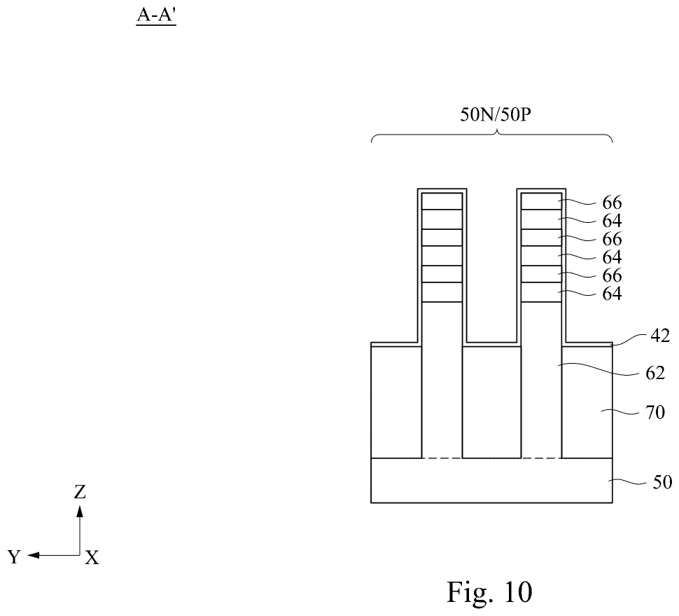

Reference is made to FIG. 9. The insulation material 68 can be recessed to form Shallow Trench Isolation (STI) regions 70, in accordance with some embodiments. The STI regions 70 are adjacent to the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. In some cases, portions of the fins 62 and/or the nanostructures 64/66 may be below a top surface of the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using dilute hydrofluoric acid (“dHF”) or the like may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further in FIG. 9, appropriate wells (not separately illustrated) may be formed in the fins 62, the nanostructures 64/66, and/or the STI regions 70. In embodiments with different well types, different implant steps for the first conductivity type device region 50N and the second conductivity type device region 50P may be achieved using a photoresist or other mask (not separately illustrated). For example, a photoresist may be formed over the fins 62, the nanostructures 64/66, and the STI regions 70 in the first conductivity type device region 50N and the second conductivity type device region 50P. The photoresist is patterned to expose the second conductivity type device region 50P. The photoresist can be formed by using a spin-on technique and can be patterned using acceptable photolithography techniques. Once the photoresist is patterned, an n-type impurity implant is performed in the second conductivity type device region 50P, and the photoresist may act as a mask to substantially prevent n-type impurities from being implanted into the first conductivity type device region 50N. The n-type impurities may include phosphorus, arsenic, antimony, or the like implanted in the region to a concentration in a range from about 1013 atoms/cm3 to about 1014 atoms/cm3. After the implant, the photoresist is removed, such as by an acceptable ashing process.

Following or prior to the implanting of the second conductivity type device region 50P, a photoresist or other mask (not separately illustrated) is formed over the fins 62, the nanostructures 64/66, and the STI regions 70 in the second conductivity type device region 50P and the first conductivity type device region 50N. The photoresist is patterned to expose the first conductivity type device region 50N. The photoresist can be formed by using a spin-on technique and can be patterned using acceptable photolithography techniques. Once the photoresist is patterned, a p-type impurity implant may be performed in the first conductivity type device region 50N, and the photoresist may act as a mask to substantially prevent p-type impurities from being implanted into the second conductivity type device region 50P. The p-type impurities may be boron, boron fluoride, indium, or the like implanted in the region to a concentration in a range from about 10¹³ atoms/cm³ to about 10¹⁴ atoms/cm3. After the implant, the photoresist may be removed, such as by an acceptable ashing process.

After the implants of the first conductivity type device region 50N and the second conductivity type device region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

Reference is made to FIG. 10. A dielectric liner 42 can be formed over the STI regions 70, the fins 62, and the nanostructures 64/66, in accordance with some embodiments. The dielectric liner 42 may be formed as a conformal layer over and along sidewalls of the fins 62 and nanostructures 64/66. The dielectric liner 42 may be formed to protect surfaces of the STI regions 70, the fins 62, and/or the nanostructures 64/66 from etching during subsequent processes, and to act as an etch stop layer in some subsequent processes. In some embodiments, portions of the dielectric liner 42 may be subsequently utilized as a dummy dielectric layer, a dummy gate dielectric, or the like. The dielectric liner 42 may comprise a silicon-based dielectric material, such as silicon oxide, silicon oxynitride, or the like. Other materials are possible. The dielectric liner 42 may be deposited or thermally grown according to acceptable techniques.

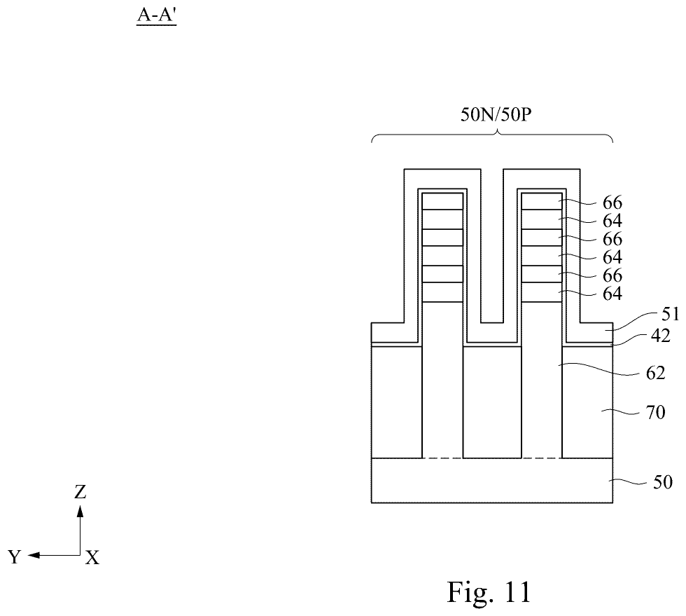

Reference is made to FIG. 11. A hard mask layer 51 can be deposited over the dielectric liner 42, in accordance with some embodiments. The hard mask layer 51 subsequently can form a hard mask 52 (see FIGS. 12A-12D) that protects some surfaces of the STI regions 70 from etching during subsequent processes. Accordingly, the hard mask 52 may be considered a protective layer or the like. The hard mask layer 51 can be deposited over the STI regions 70 and over and along sidewalls of the fins 62 and/or the nanostructures 64/66. Accordingly, the hard mask layer 51 may be deposited as a continuous layer, in some cases. The hard mask layer 51 may comprise one or more materials that have a high etching selectivity from the etching of the materials of the dielectric liner 42, the STI regions 70, the fins 62, and/or the nanostructures 64/66. In some embodiments, the hard mask layer 51 may comprise a nitride, such as silicon nitride, silicon oxynitride, a silicon oxycarbonitride, or the like.

In other embodiments, the hard mask layer 51 comprises an oxide, such as hafnium oxide, zirconium oxide, or the like. Other materials are possible, and the hard mask layer 51 may comprise multiple layers of different materials, in some cases. The hard mask layer 51 may be deposited using a suitable process, such as CVD, plasma-enhanced CVD (PECVD), ALD, or the like. The deposition process may be conformal. In some cases, portions of the hard mask layer 51 deposited on sidewall surfaces (e.g., vertical surfaces) may be thinner than portions of the hard mask layer 51 deposited on lateral surfaces (e.g., top surfaces).

Reference is made to FIGS. 12A-12D. Upper portions of the hard mask layer 51 can be removed to form the hard mask 52, in accordance with some embodiments. The upper portions of the hard mask layer 51 may include portions along sidewalls of the fins 62, portions along sidewalls of the nanostructure 64/66, and/or portions over top surfaces of the nanostructures 64/66. As shown in FIGS. 12A and 12B, the remaining portions of the hard mask layer 51 over top surfaces of the STI regions 70 form the hard mask 52. The upper portions of the hard mask layer 51 may be removed using one or more acceptable etch processes, such as a dry etch, a wet etch, or a combination thereof. The etch process may be anisotropic. In some cases, the etch process may thin lateral portions of the hard mask layer 51 that form the hard mask 52. As shown in FIGS. 12A and 12B, the dielectric liner 42 is between the hard mask 52 and the STI regions 70. Further, top surfaces of the hard mask 52 may have a flat surface as illustrated, a convex surface, a concave surface (such as dishing), or a combination thereof.

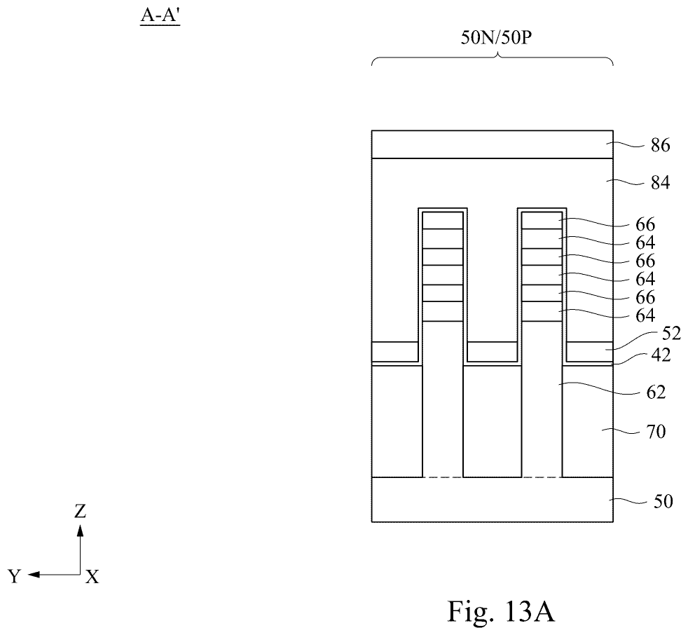

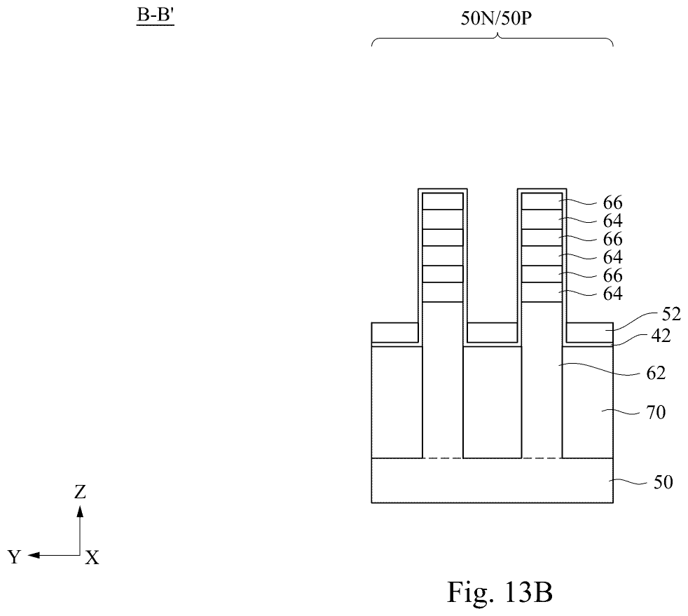

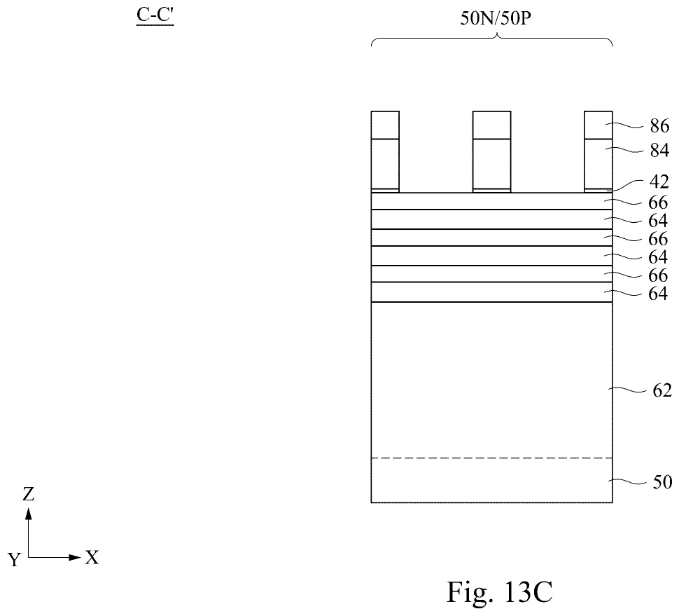

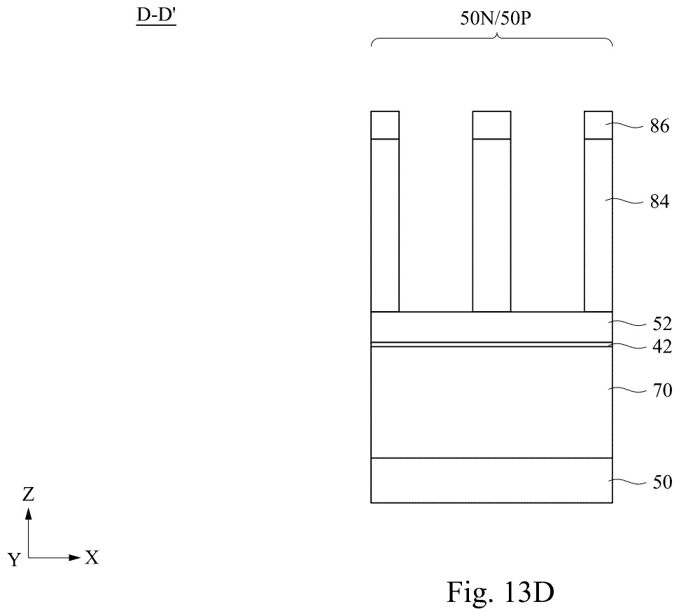

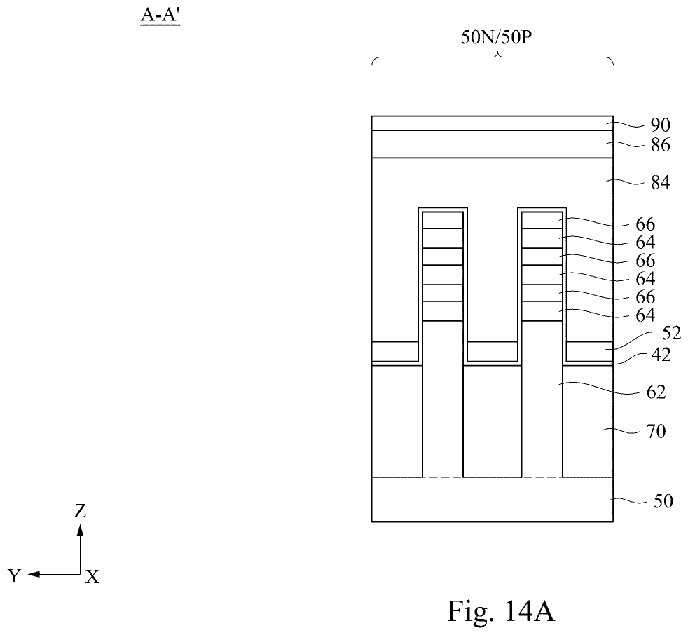

Reference is made to FIGS. 13A-13D. Dummy gates 84 and masks 86 can be formed over the hard mask 52 and the dielectric liner 42, in accordance with some embodiments. In some embodiments, a dummy gate layer is formed over the hard mask 52 and nanostructures 64/66, and along sidewalls of the fins 62 and nanostructures 64/66. A mask layer is formed over the dummy gate layer. The dummy gate layer may be deposited over the dummy dielectric layer and then planarized, such as by a CMP process or the like. The dummy gate layer may be formed of a conductive or non-conductive material and may be selected from a group including amorphous silicon, polycrystalline-silicon (polysilicon), polycrystalline silicon germanium (poly-SiGe), metallic nitrides, metallic silicides, metallic oxides, and metals. The material of the dummy gate layer may be deposited by CVD, physical vapor deposition (PVD), sputter deposition, or another suitable technique. The dummy gate layer may be formed of other materials that have a high etching selectivity from the etching of insulation materials, e.g., hard mask 52, the dielectric liner 42, and/or the STI regions 70. The dummy gate layer may be formed of multiple layers of different materials, in some cases. The mask layer may be deposited over the dummy gate layer. The mask layer may be formed of a dielectric material such as silicon nitride, silicon oxynitride, silicon oxide, or the like. The mask layer may be formed of multiple layers of different materials, in some cases.

Subsequently, the mask layer can be patterned using acceptable photolithography and etching techniques to form masks 86. The pattern of the masks 86 then may be transferred to the dummy gate layer form dummy gates 84. In some embodiments, the pattern of the masks 86 is also transferred to the dielectric liner 42, with portions of the dielectric liner 42 on the fins 62 and/or the nanostructures 64/66 forming dummy gate dielectrics. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise (e.g., longitudinal) direction of respective fins 62. The masks 86 can optionally be removed after patterning, such as by any acceptable etching technique. In this example, a single dummy gate layer and a single mask layer are formed across the first conductivity type device region 50N and the second conductivity type device region 50P.

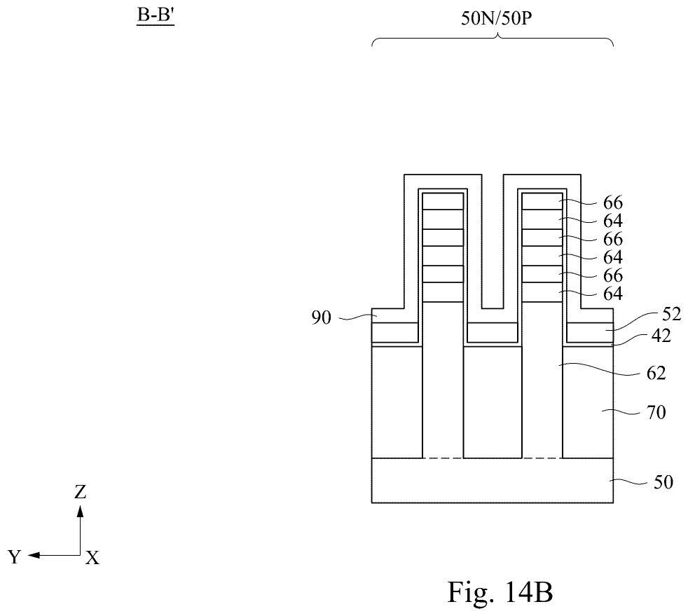

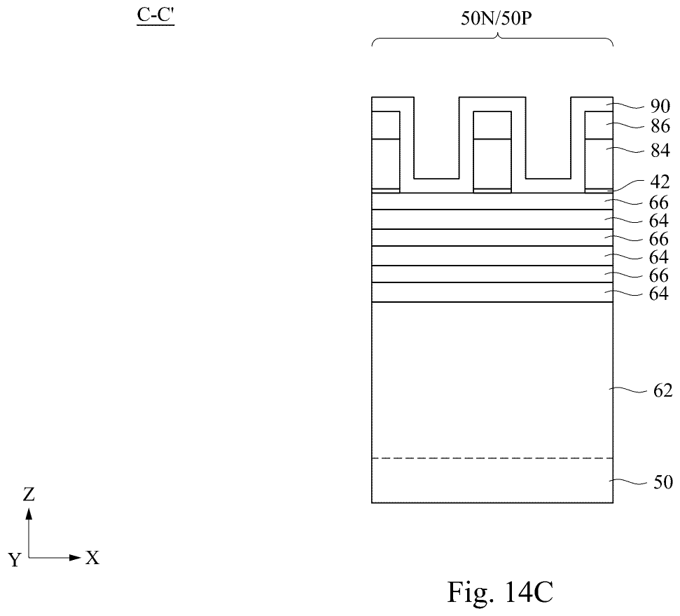

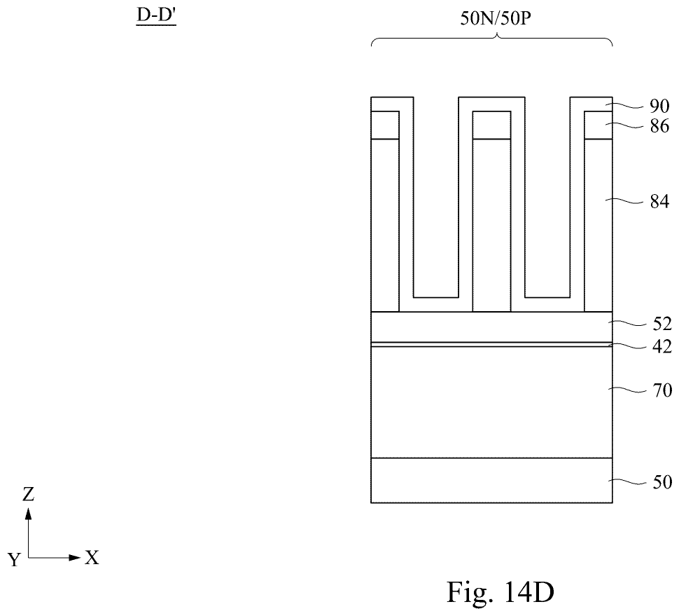

Reference is made to FIGS. 14A-14D. A spacer layer 90 can be conformally formed over the structure, in accordance with some embodiments. The spacer layer 90 can be formed over the nanostructures 64/66 and the hard mask 52. The spacer layer 90 can be also formed on exposed sidewalls of the masks 86 (if present), the dummy gates 84, the dielectric liner 42, the nanostructures 64/66, and/or the fins 62. The spacer layer 90 may be formed of one or more dielectric material(s). FIGS. 14A-14D show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as CVD, ALD, or the like. Other insulation materials formed by any acceptable process may be used. The spacer layer 90 can be subsequently etched to form spacers.

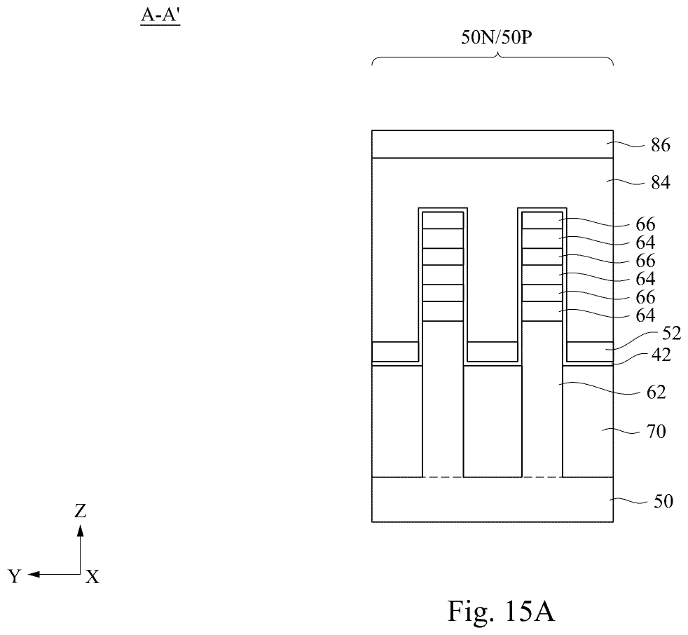

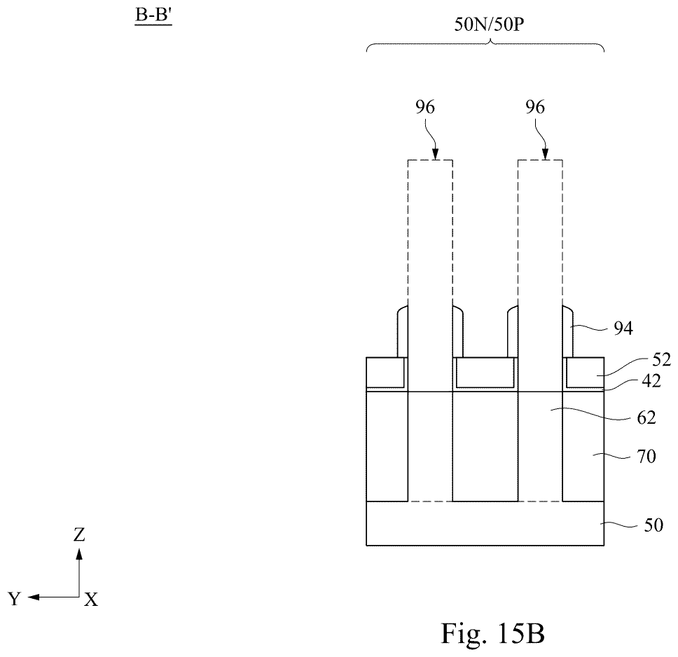

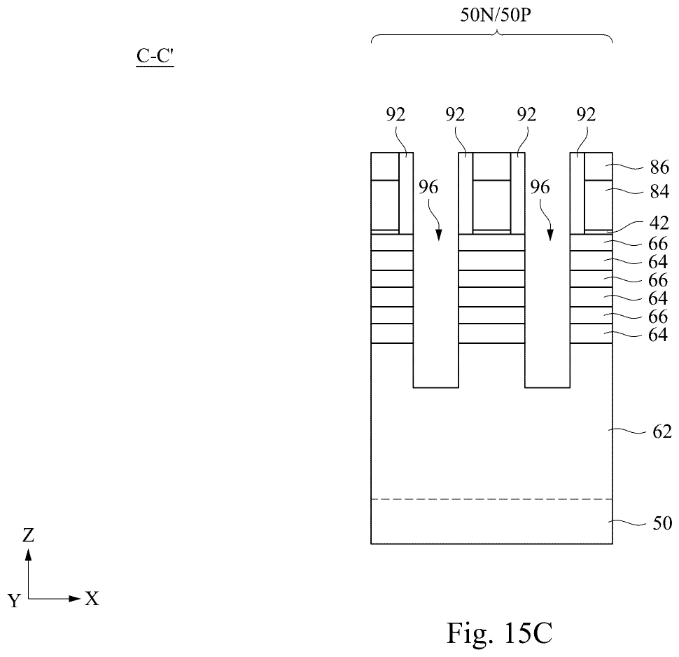

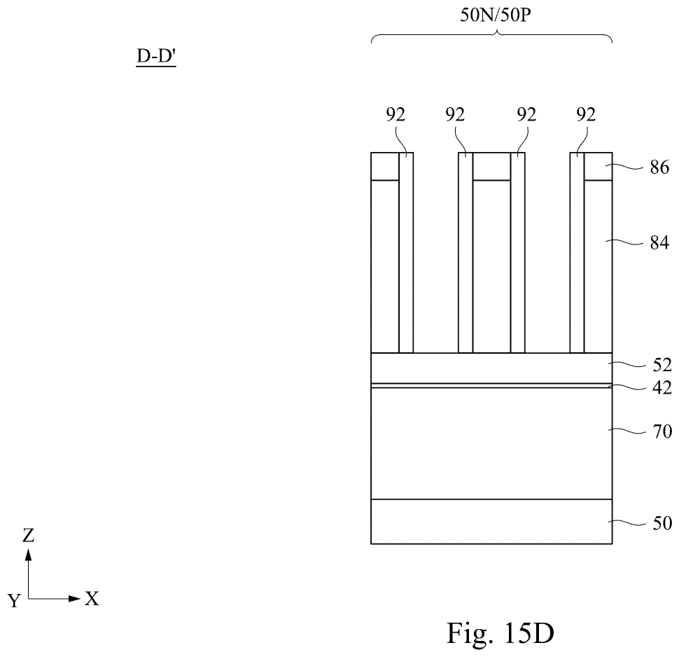

Reference is made to FIGS. 15A-15D. The spacer layer 90 can be patterned to form gate spacers 92 (see FIGS. 15C and 15D) and fin spacers 94 (see FIG. 15B), in accordance with some embodiments. Any acceptable etching process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 may have straight sidewalls or may have curved sidewalls. In some embodiments, the etching stops on the hard mask 52. In other embodiments, the hard mask 52 and/or the STI regions 70 may also be etched when patterning the spacer layer 90. For example, the etching may recess portions of the hard mask 52 between fins 62 and/or between gate spacers 92, or may etch through the hard mask 52 and recess portions of the STI regions 70 between fins 62 and/or between gate spacers 92. The etching may stop on the hard mask 52, may recess (e.g., thin) the hard mask 52, or may etch through the hard mask 52, depending on the characteristics of the etching process used. The gate spacers 92 and/or the fin spacers 94 may have straight sidewalls (as illustrated) or may have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the first conductivity type device region 50N, while exposing the second conductivity type device region 50P, and appropriate type (e.g., p-type) impurities may be implanted into the fins 62 and the nanostructures 64/66 exposed in the second conductivity type device region 50P. The mask may then be removed. Subsequently, a mask, such as a photoresist, may be formed over the second conductivity type device region 50P while exposing the first conductivity type device region 50N, and appropriate type impurities (e.g., n-type) may be implanted into the fins 62 and the nanostructures 64/66 exposed in the first conductivity type device region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1015 atoms/cm3 to about 1019 atoms/cm3. An anneal may be used to repair implant damage and to activate the implanted impurities.

It is noted that the previous disclosure describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 15A-15D, source/drain recesses 96 can be patterned in the fins 62, the nanostructures 64/66, and the substrate 50, in accordance with some embodiments. Epitaxial source/drain regions can be subsequently formed in the source/drain recesses 96. The source/drain recesses 96 may extend through the nanostructures 64/66 and into the fins 62, and in some embodiments may further extend into the substrate 50. In some embodiments, the fins 62 may be etched such that the bottom surfaces of the source/drain recesses 96 are about level with or higher than top surfaces of the STI regions 70. In other embodiments, bottom surfaces of the source/drain recesses 96 are lower than the top surfaces of the STI regions 70.

The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and/or the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth. In some embodiments, the etching may etch the hard mask 52, which may form recesses that extend into the STI regions 70 between gate spacers 92.

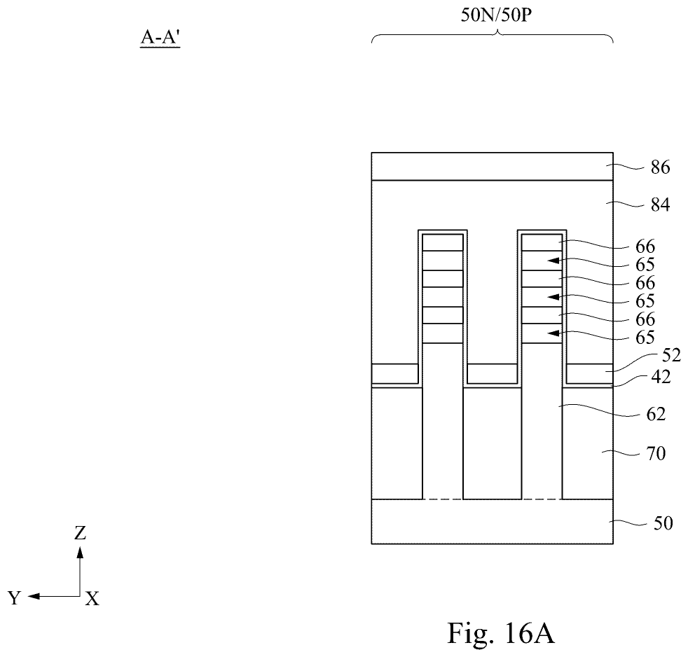

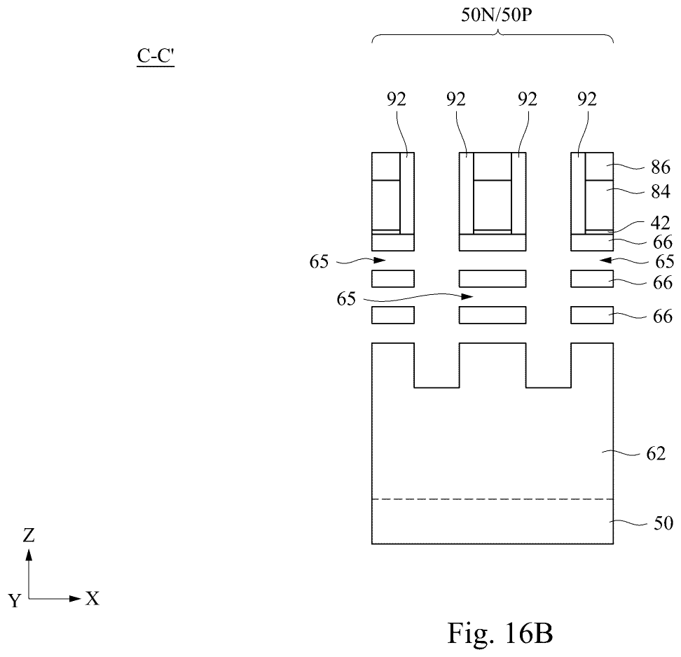

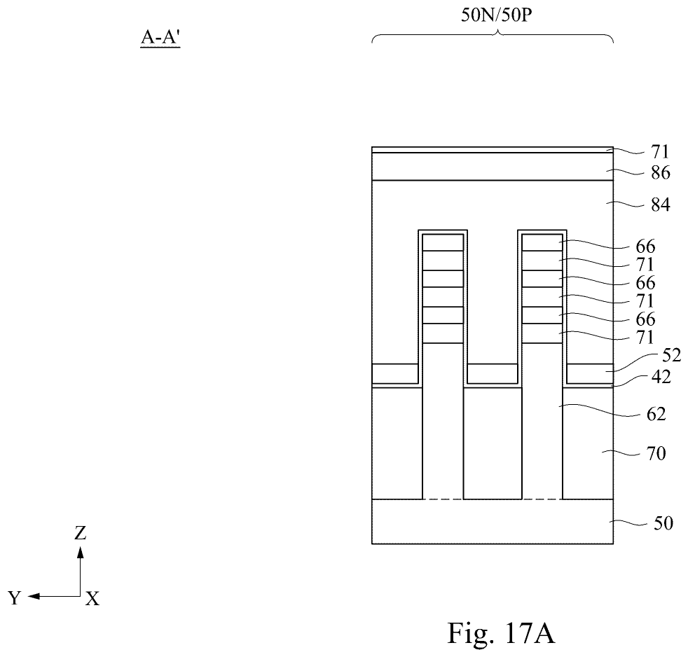

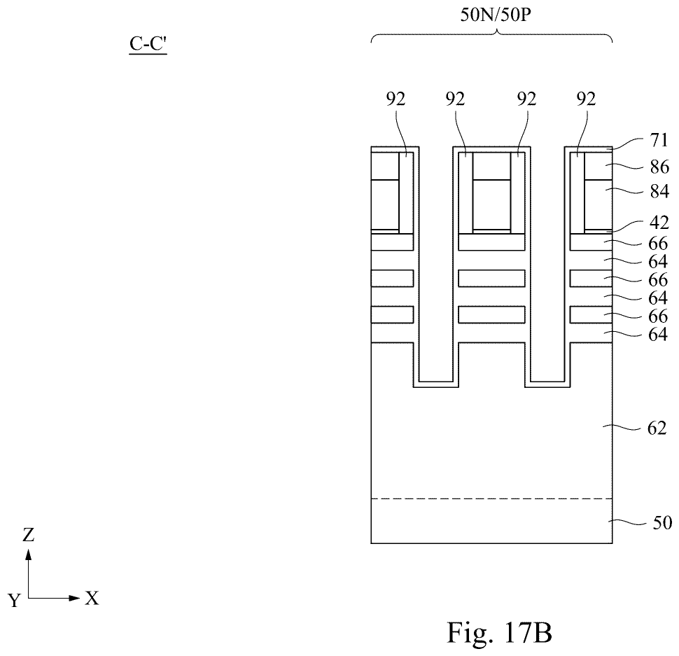

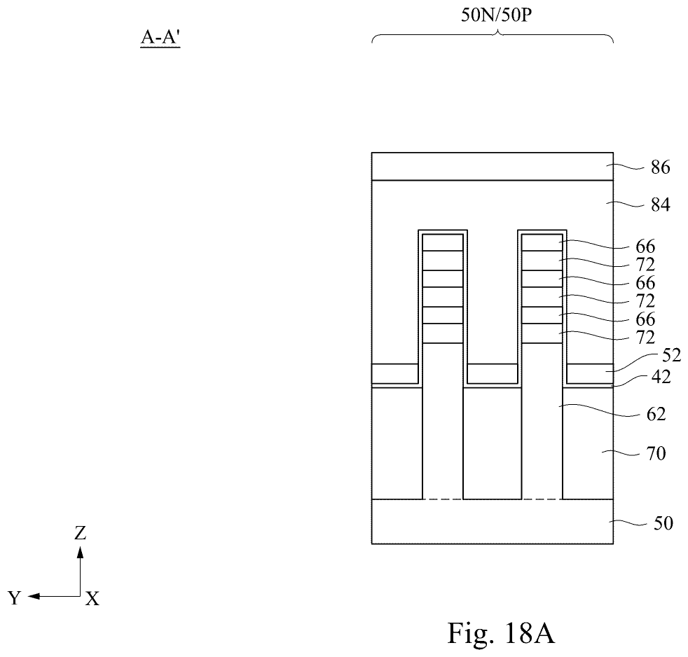

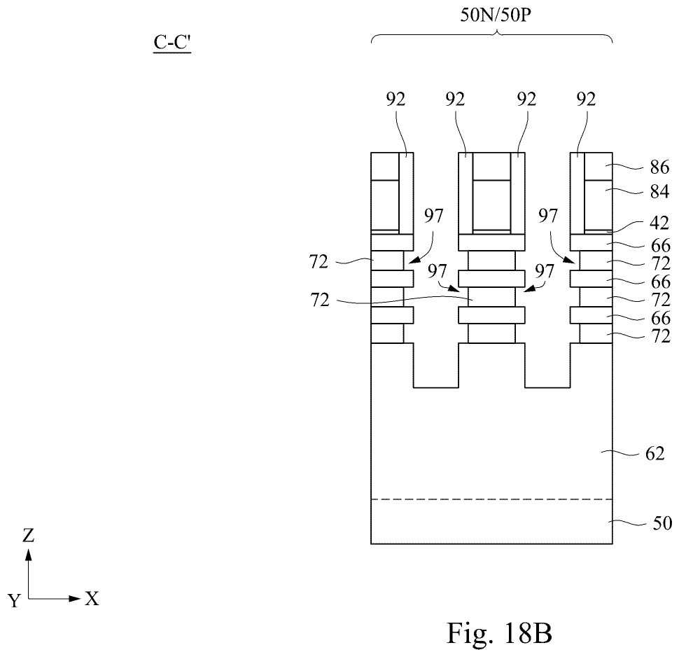

Reference is made to FIGS. 16A-18B. The first nanostructures 64 (see FIGS. 15A-15D) are replaced with a dummy material 71 (see FIGS. 17A and 17B) to form dummy regions 72 (see FIGS. 17A-18B), in accordance with some embodiments. In FIGS. 16A and 16B, the remaining portions of the first nanostructures 64 can be removed to form openings 65 in regions between the second nanostructures 66, in accordance with some embodiments. The remaining portions of the first nanostructures 64 may be removed using an etching process that is performed through the source/drain recesses 96. The etching process may include any acceptable etching process that selectively etches the material of the first nanostructures 64 at a faster rate than the material of the second nanostructures 66, the fins 62, and/or the dielectric liner 42. The etching process may include a wet etch process and/or a dry etch process, and the etching may isotropic. In some embodiments, a trim process (not illustrated) is performed to decrease the thicknesses of the exposed portions of the second nanostructures 66 and expand the openings 65. Hereinafter, the second nanostructures 66 may be referred to as nanostructures 66, and the collections of vertically adjacent nanostructures 66 over each fin 62 may be referred to as “stacks” of nanostructures 66.

In FIGS. 17A-18B, the dummy material 71 is deposited to form dummy regions 72, in accordance with some embodiments. In some cases, the dummy material 71 may be considered a sacrificial material or a sacrificial oxide. In some cases, the dummy regions 72 may be considered sacrificial regions, dielectric dummy regions, dummy nanostructures, dummy gate regions, or disposable oxide interposers (DOI). Replacing the first nanostructures 64 with dummy regions 72 may provide advantages. For example, in subsequent source/drain formation steps, one or more high temperature processes may be performed to, for example, activate the dopants in the source/drain regions. When the material of the first nanostructures 64 (e.g., silicon germanium or the like) is exposed to high temperatures, germanium intermixing and increased roughness at interfaces between the nanostructures 64 and 66 may result. Such manufacturing defects may degrade the performance of the resulting transistor devices. For example, when germanium diffuses into the second nanostructures 66, germanium residue may remain in channel regions of the resulting transistor devices, which negatively affects the performance of the channel regions. Additionally, the intermixing may result in etching selective to either the first nanostructures 64 or the second nanostructures 66 to be less effective and less defined. This can result in, for example, portions of the second nanostructures 66 being undesirably removed, which can damage features, reduce yield, and/or degrade device performance. By replacing the first nanostructures 64 with an insulating material (e.g., the dummy material 71) prior to the high temperature processes (e.g., source/drain annealing), manufacturing defects can be reduced and device performance can be improved. Additionally, the selectivity of etching between the dummy material 71 and the material of the second nanostructures 66 may be greater than the selectivity of etching between the nanostructures 64 and 66, allowing for improved etching definition and less etching of the second nanostructures 66.

In FIGS. 17A and 17B, a dummy material 71 can be deposited in the recesses 96 and in the openings 65, in accordance with some embodiments. The dummy material 71 may be deposited by a conformal deposition process, such as CVD, ALD, or the like. The dummy material 71 may comprise an insulating material such as silicon oxide or the like that can be selectively etched from the nanostructures 66 and the fins 62. As shown in FIGS. 17A and 17B, the dummy material 71 may fill or overfill the openings 65 and may cover sidewalls of the nanostructures 66. The dummy material 71 may cover top surfaces of the fins 62. In some embodiments, the dummy material 71 does not completely fill the source/drain recesses 96.

In FIGS. 18A and 18B, the dummy material 71 can be etched to form the dummy regions 72, in accordance with some embodiments. The etching may be isotropic or anisotropic. For example, the dummy material 71 may be etched using a wet etch process, such as dHF or the like. In some embodiments, the etching is performed until sidewalls of the dummy material 71 are recessed past sidewalls of the nanostructures 66, forming sidewall recesses 97. Accordingly, the dummy regions 72 may have a width that is smaller than a width of the nanostructures 66. In some cases, the sidewall recesses 97 may be considered part of the source/drain recesses 96. Although sidewalls of the dummy regions 72 within the sidewall recesses 97 are illustrated as being flat, the sidewalls may be concave or convex.

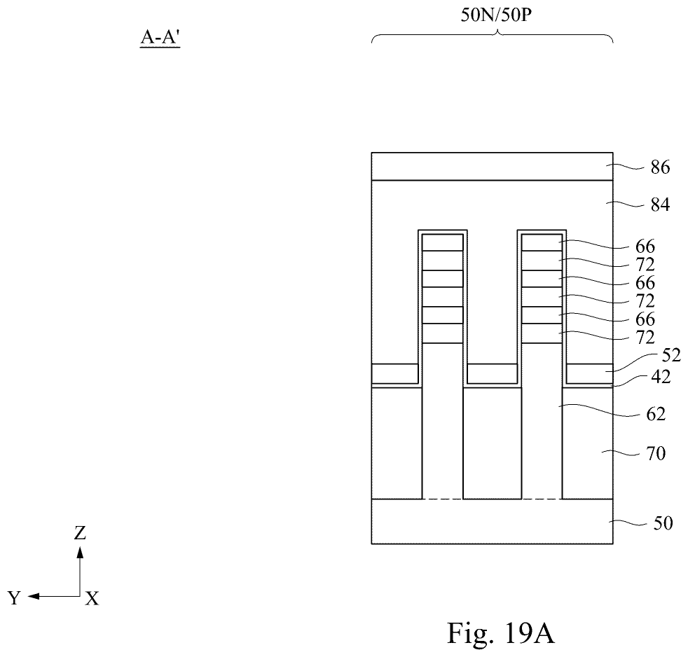

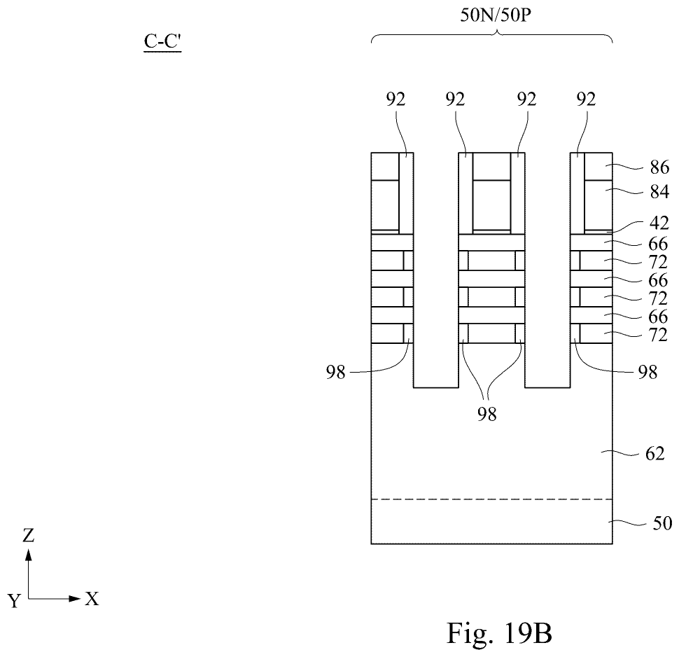

Reference is made to FIGS. 19A and 19B. Inner spacers 98 can be formed in the sidewall recesses 97, in accordance with some embodiments. In other words, inner spacers 98 can be formed on the sidewalls of the dummy regions 72. As will be subsequently described in greater detail, source/drain regions can be subsequently formed in the source/drain recesses 96, and the dummy regions 72 are subsequently replaced with corresponding gate structures G. The inner spacers 98 can act as isolation features between the subsequently formed source/drain regions and the subsequently formed gate structures G. Further, the inner spacers 98 may be used to prevent damage to the subsequently formed source/drain regions by subsequent etch processes.

In some embodiments, the inner spacers 98 are formed by conformally depositing an insulating material in the source/drain recesses 96 and in the sidewall recesses 97 and subsequently etching the insulating material. The insulating material may be silicon nitride, silicon oxynitride, or the like. However, any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98. An inner spacer 98 may have a thickness that is smaller than, about the same as, or greater than a thickness of an adjacent dummy region 72.

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat in FIGS. 19A and 19B, the sidewalls of the inner spacers 98 may be concave or convex.

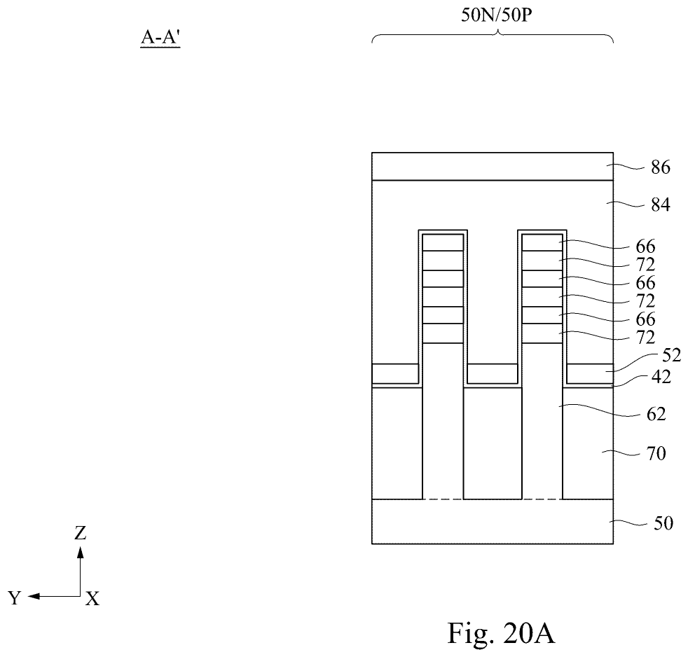

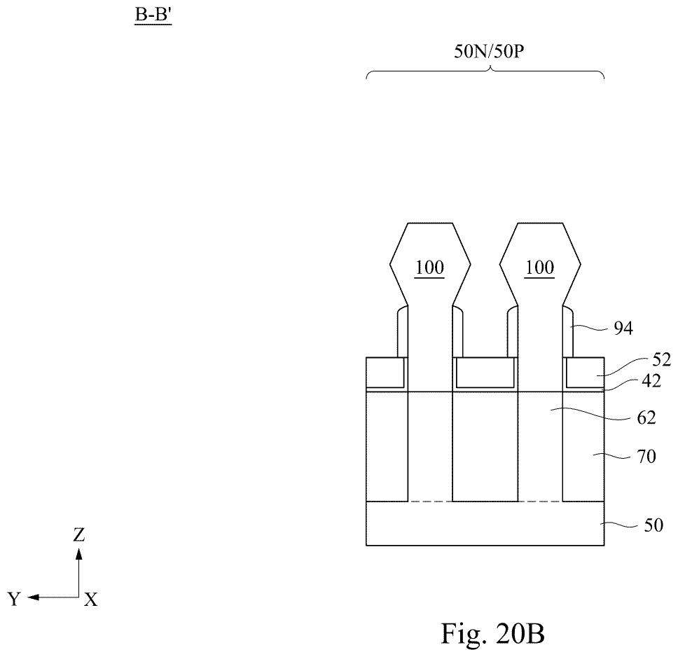

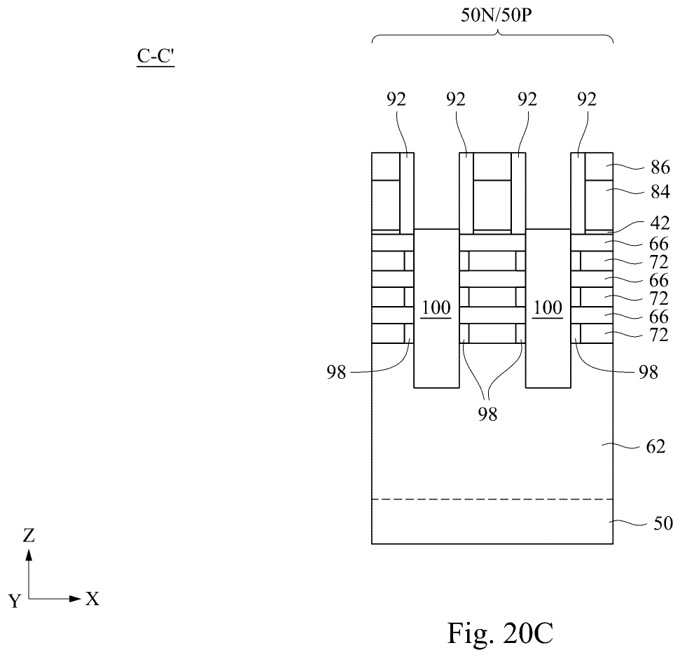

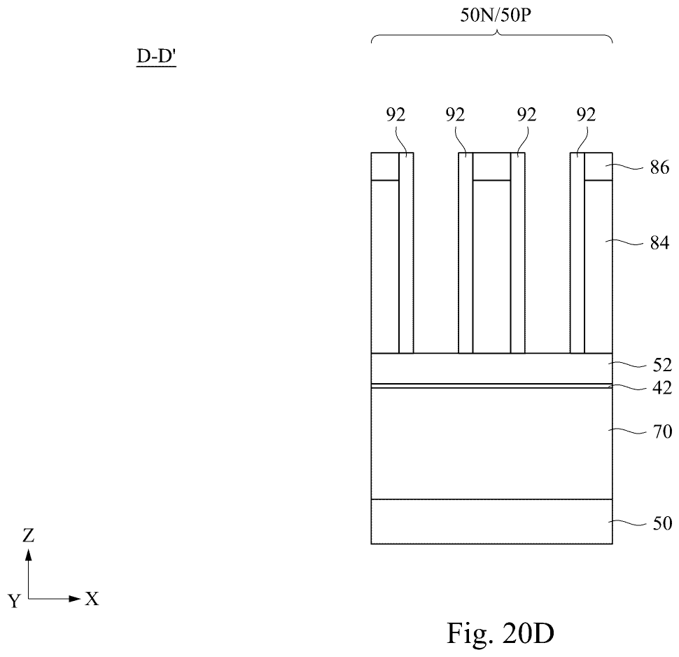

Reference is made to FIGS. 20A-20D. Epitaxial source/drain regions 100 can be formed in the source/drain recesses 96 of the first conductivity type device region 50N and in the source/drain recesses 96 of the second conductivity type device region 50P, in accordance with some embodiments. The epitaxial source/drain regions 100 may also be referred to as “source/drain regions 100.” For example, the epitaxial source/drain regions 100 in the first conductivity type device region 50N may be referred to as “n-type source/drain regions 100,” and the epitaxial source/drain regions 100 in the second conductivity type device region 50P may be referred to as “p-type source/drain regions 100.” The n-type source/drain regions 100 may be formed before, after, or simultaneously with the formation of the p-type source/drain regions 100. The epitaxial source/drain regions 100 may be formed by an epitaxy process, such as such as vapor phase epitaxy (VPE), molecular beam epitaxy (MBE), or the like.

In some embodiments, the epitaxial source/drain regions 100 exert stress on channel regions of the nanostructures 66 within the first conductivity type device region 50N and/or within the second conductivity type device region 50P, thereby improving performance. The epitaxial source/drain regions 100 can be formed in the source/drain recesses 96 such that each dummy gate 84 of the second conductivity type device region 50P is disposed between respective neighboring pairs of the epitaxial source/drain regions 100. In some embodiments, the gate spacers 92 can be used to separate the epitaxial source/drain regions 100 from the dummy gates 84, and the inner spacers 98 can be used to separate the epitaxial source/drain regions 100 from the nanostructures 66 by an appropriate lateral distance such that the epitaxial source/drain regions 100 do not short out with subsequently formed gates of the resulting nanostructure-FETs.

The epitaxial source/drain regions 100 in the first conductivity type device region 50N may be formed by masking the second conductivity type device region 50P. Then, n-type source/drain regions 100 are epitaxially grown in the source/drain recesses 96 in the first conductivity type device region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like.

The epitaxial source/drain regions 100 in the second conductivity type device region 50P may be formed by masking the first conductivity type device region 50N. Then, p-type source/drain regions 100 are epitaxially grown in the source/drain recesses 96 in the second conductivity type device region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon germanium, boron doped silicon germanium, germanium, germanium tin, or the like.

The epitaxial source/drain regions 100, nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 100 may be in situ doped during growth.

As a result of the epitaxy processes used to form the epitaxial source/drain regions 100 in the first conductivity type device region 50N and the second conductivity type device region 50P, upper surfaces of the epitaxial source/drain regions 100 have facets which expand laterally outward beyond sidewalls of the nanostructures 66. In some embodiments, adjacent epitaxial source/drain regions 100 remain separated after the epitaxy process is completed, as illustrated by FIG. 20B. In other embodiments, these facets cause adjacent epitaxial source/drain regions 100 of a same nanostructure-FET to merge. In the embodiments illustrated in FIG. 20B, the fin spacers 94 may be formed on top surfaces of the STI regions 70, thereby blocking epitaxial growth. In some other embodiments, the fin spacers 94 may cover portions of the sidewalls of the nanostructures 66, further blocking the epitaxial growth. In some other embodiments, the spacer etch used to form the fin spacers 94 may be adjusted to remove the spacer material to allow the epitaxially grown region to extend to the surface of the hard mask 52.

The n-type source/drain regions 100 and/or the p-type source/drain regions 100 may comprise one or more semiconductor material layers. Any number of semiconductor material layers may be used for the epitaxial source/drain regions 100. Each semiconductor material layer may be formed of different semiconductor materials and may be doped to different dopant concentrations. In embodiments in which the epitaxial source/drain regions 100 can comprise three semiconductor material layers, the first semiconductor material layer may be deposited, the second semiconductor material layer may be deposited over the first semiconductor material layer, and the third semiconductor material layer may be deposited over the second semiconductor material layer. In some embodiments, the first semiconductor material layer may have a dopant concentration less than the second semiconductor material layer and greater than the third semiconductor material layer. Other semiconductor material layers, dopant concentrations, or configurations thereof are possible.

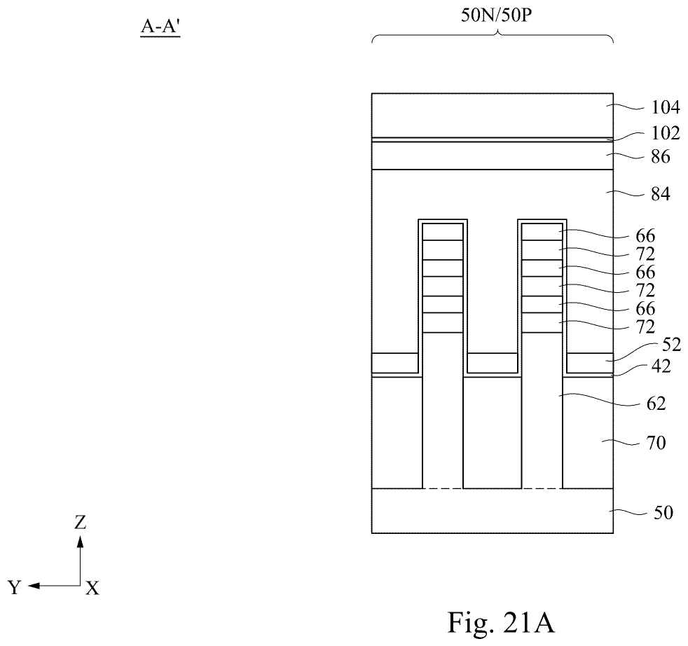

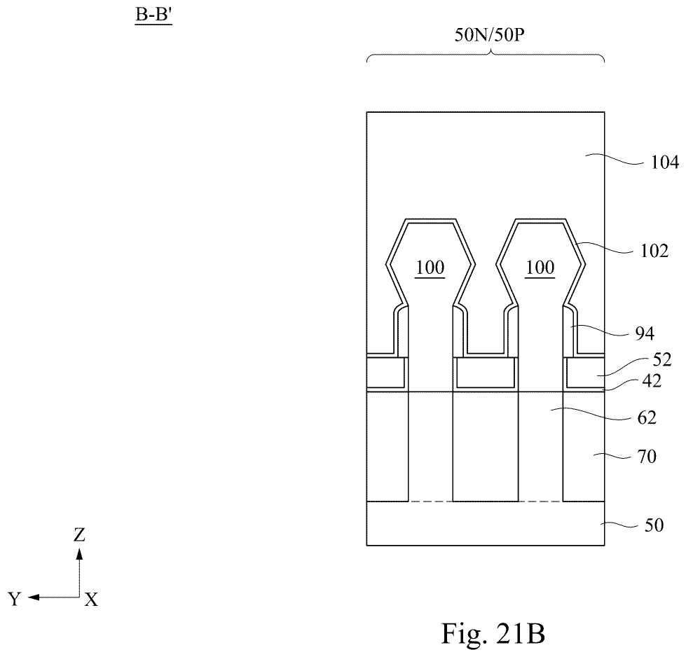

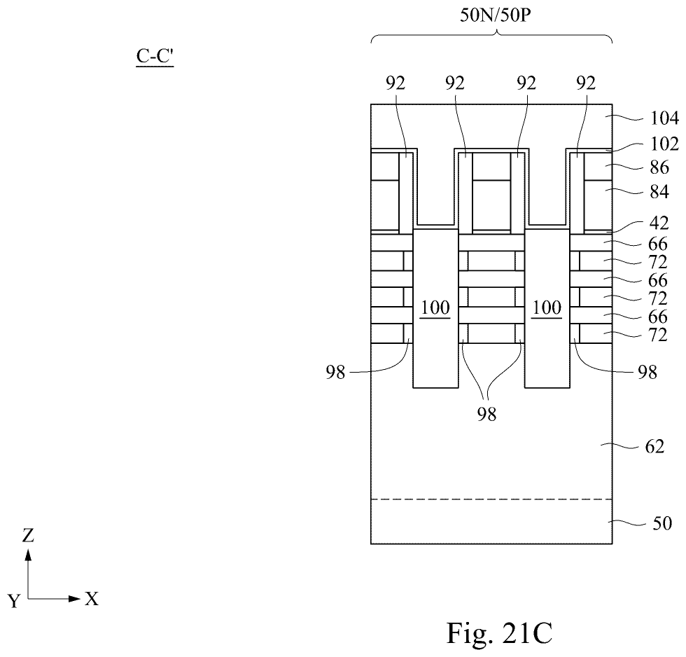

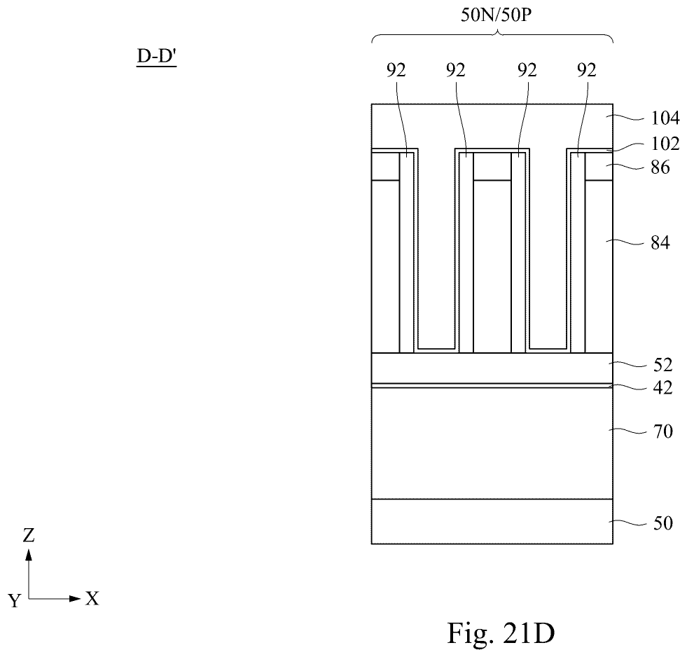

Reference is made to FIGS. 21A-21D. A first inter-layer dielectric (ILD) 104 can be deposited over the epitaxial source/drain regions 100, the fin spacers 94, the gate spacers 92, the masks 86 (if present), the hard mask 52, and/or the dummy gates 84. The ILD layer 104 may be formed of a dielectric material, which may be deposited by any suitable method, such as CVD, PECVD, or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some cases, the ILD layer 104 may extend below top surfaces of the hard mask 52 and/or below bottom surfaces of the epitaxial source/drain regions 100.

In some embodiments, a contact etch stop layer (CESL) 102 can be formed between the ILD layer 104 and the epitaxial source/drain regions 100, the fin spacers 94, the gate spacers 92, the masks 86 (if present), the hard mask 52, and/or the dummy gates 84. The CESL 102 may be formed of a dielectric material having a high etching selectivity from the etching of the ILD layer 104, such as silicon nitride, silicon oxide, silicon oxynitride, a combination thereof, or the like, which may be formed using any suitable deposition process, such as CVD, ALD, or the like. In other embodiments, the masks 86 and portions of the gate spacers 92 along sidewalls of the masks 86 are removed using a planarization process (e.g., a CMP or grinding process) prior to deposition of the CESL 102 and the ILD layer 104.

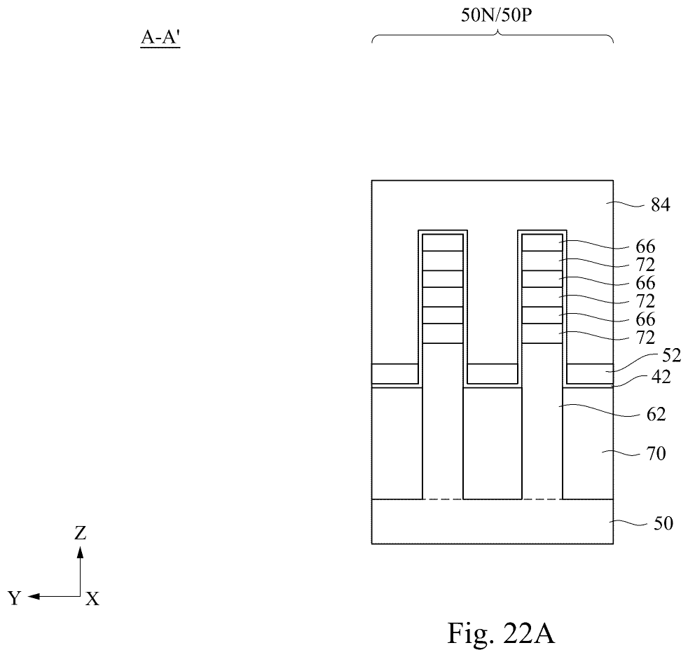

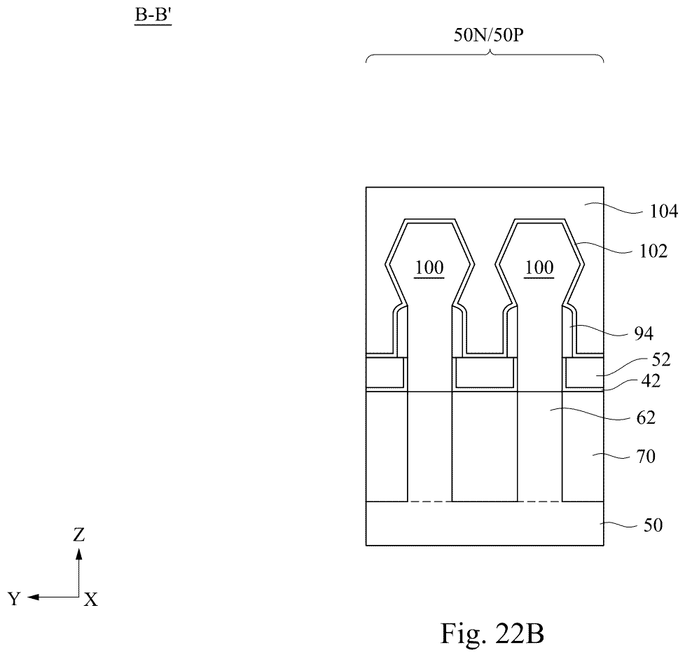

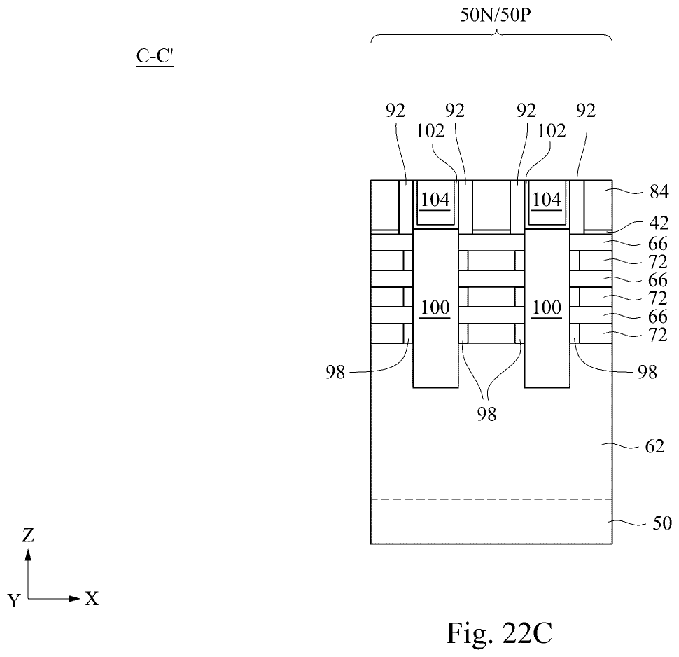

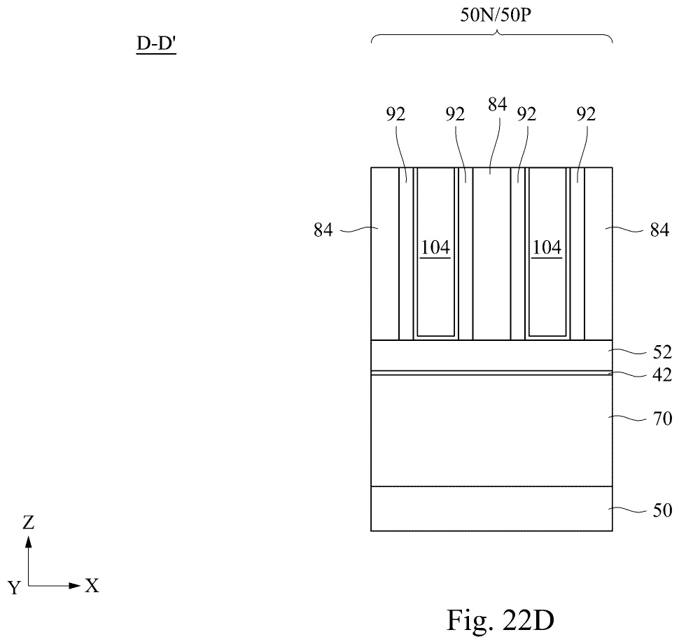

Reference is made to FIGS. 22A-22D. A removal process can be performed to level the top surfaces of the ILD layer 104 with the top surfaces of the gate spacers 92 and the dummy gates 84, in accordance with some embodiments. In some embodiments, the planarization process can remove the masks 86 and portions of the gate spacers 92 along sidewalls of the masks 86. The removal process may include a planarization process such as a CMP process, a grinding process, an etch-back process, a combination thereof, or the like. After the planarization process, top surfaces of the ILD layer 104, the gate spacers 92, and the dummy gates 84 may be substantially level or coplanar (within process variations). Accordingly, the top surfaces of the dummy gates 84 may be exposed through the ILD layer 104. In other embodiments, the planarization process does not remove the masks 86. In such embodiments, after the planarization process, top surfaces of the ILD layer 104, the gate spacers 92, and the masks 86 may be substantially level or coplanar (within process variations).

In some embodiments, a capping layer (not illustrated) is formed over the ILD layer 104. The capping layer may be formed, for example, by recessing the ILD layer 104 using a suitable etching process and then depositing an insulating material over the structure. The insulating material may comprise one or more dielectric materials such as silicon nitride, silicon oxynitride, or the like. A planarization process (e.g., a CMP or grinding process) may then be performed to remove excess insulating material from over the structure, with the remaining insulating material over the ILD layer 104 forming the capping layer. In other embodiments, the capping layer is not formed.

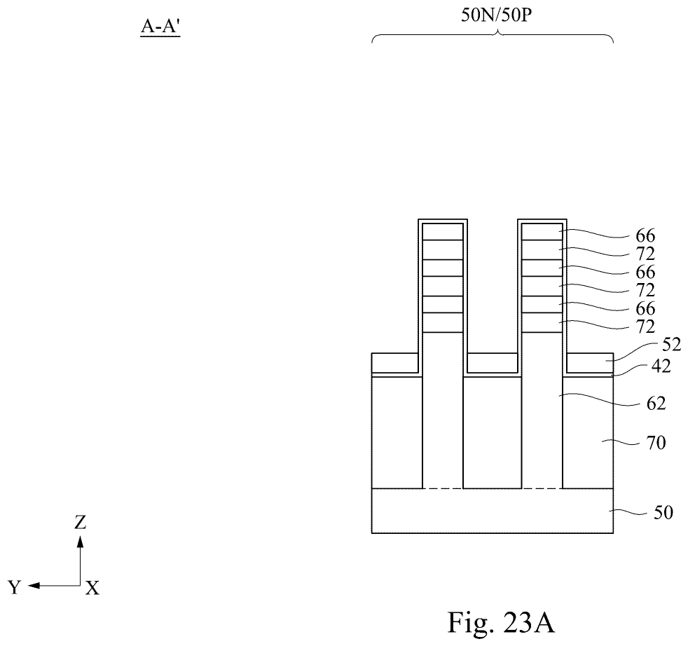

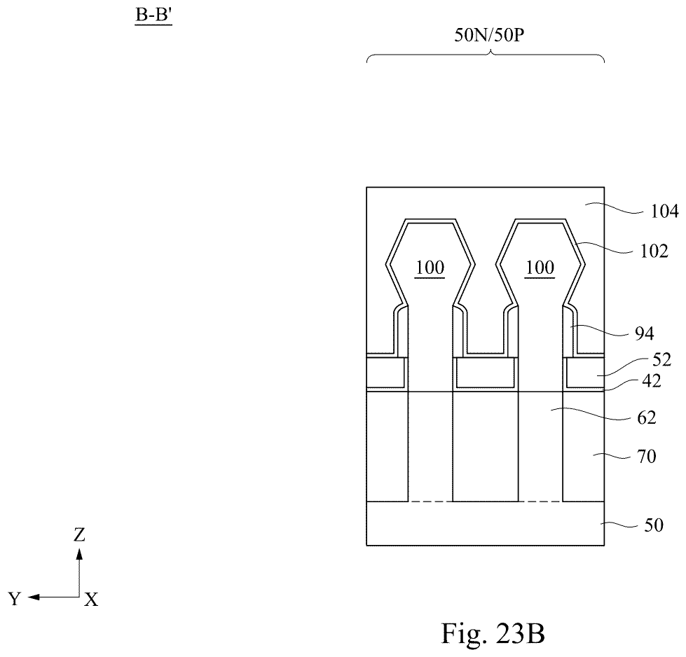

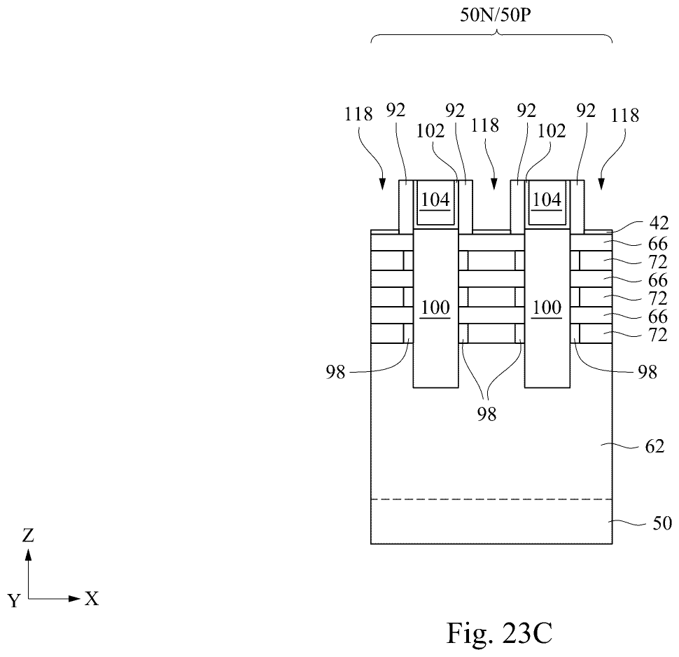

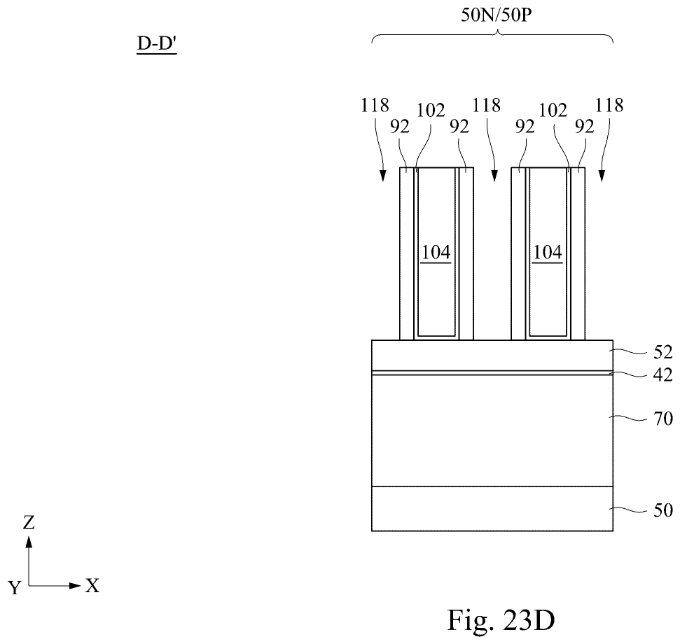

Reference is made to FIGS. 23A-23D. The dummy gates 84 can be removed in one or more etching steps, in accordance with some embodiments. Removing the dummy gates 84 can form recesses 118 (see FIGS. 23C and 23D) between the gate spacers 92. In some embodiments, the dummy gates 84 can be removed by an anisotropic dry etching process. For example, the etching process may include a dry etch process using reaction gas(es) that selectively etch the material of the dummy gates 84 at a faster rate than the materials of the ILD layer 104, and the gate spacers 92. In other embodiments, a selective wet etching process may be used to remove the dummy gates 84. During the removal, the dielectric liner 42 and/or the hard mask 52 may be used as an etch stop layers when the dummy gates 84 are etched.

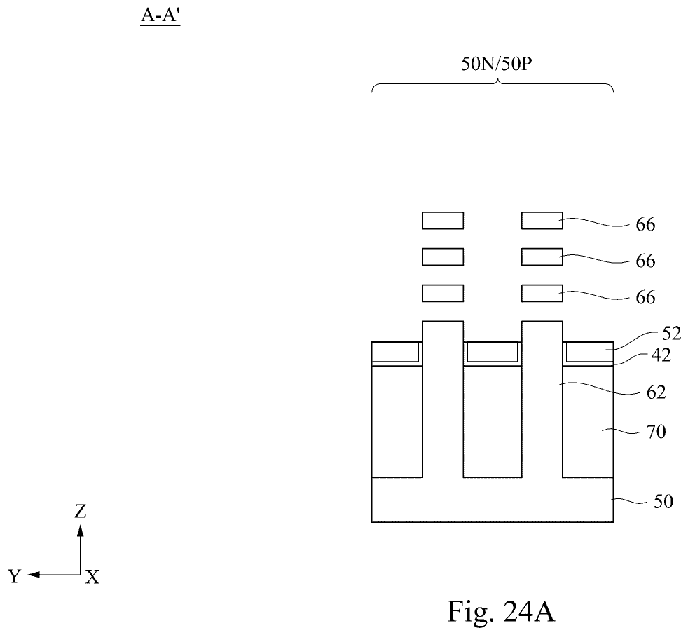

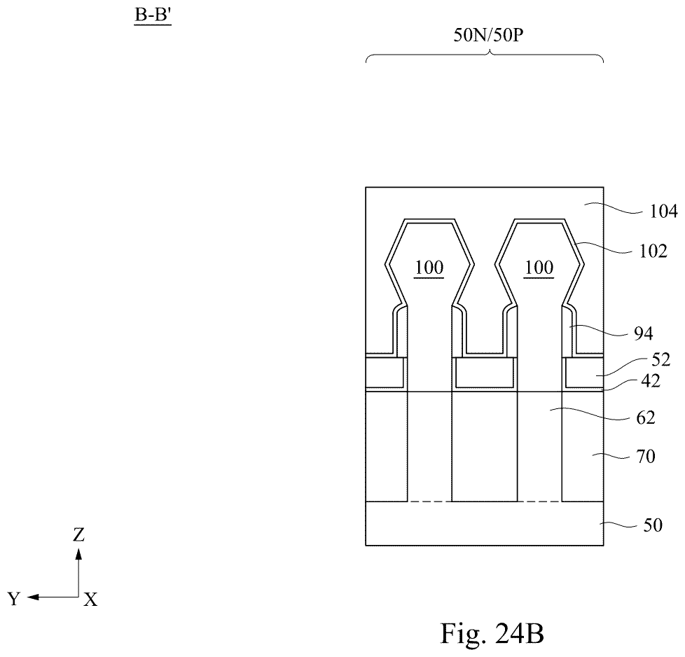

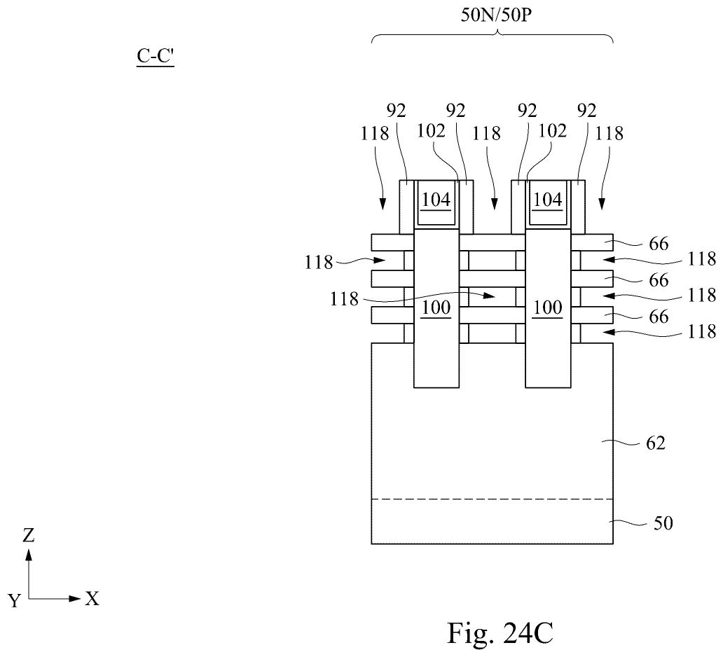

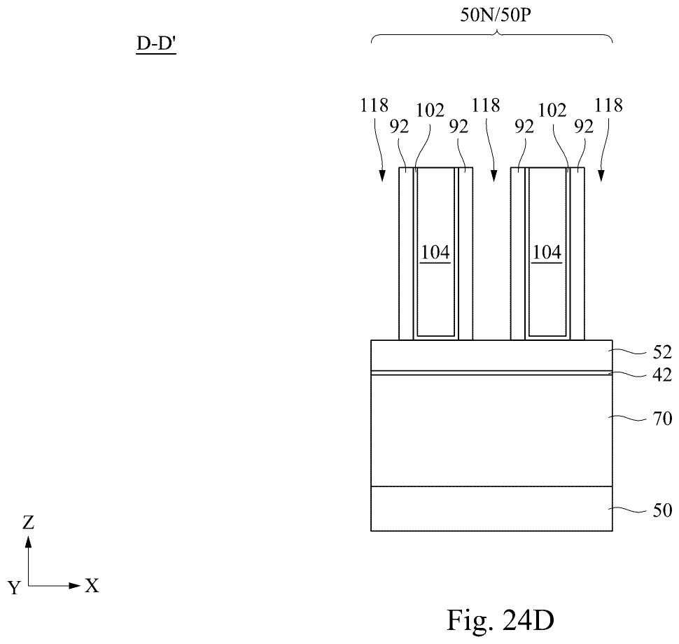

Reference is made to FIGS. 24A-24D. The dummy regions 72 can be removed, extending the recesses 118, in accordance with some embodiments. In some embodiments, the exposed regions of the dielectric liner 42 can be also removed along with the dummy regions 72. Removing the dielectric liner 42 and the dummy regions 72 may include an isotropic wet etching process or the like. The etching process may use etchants which are selective to the materials of the dielectric liner 42 and the dummy regions 72, while the nanostructures 66 remain relatively unetched. The hard mask 52 protects the STI regions 70 from the etching process. The capping layer (if present) may protect the ILD layer 104 from the etching process.

The dummy material 71 of the dummy regions 72 may be completely removed, or a residue of the dummy material 71 may remain on some sidewall portions of the inner spacers 98 in the recesses 118. After removing the dummy regions 72, each recess 108 exposes portions of nanostructures 66, which act as channel regions in subsequently completed nanostructure-FETs. Portions of the nanostructures 66 which act as the channel regions are disposed between neighboring pairs of the epitaxial source/drain regions 100.

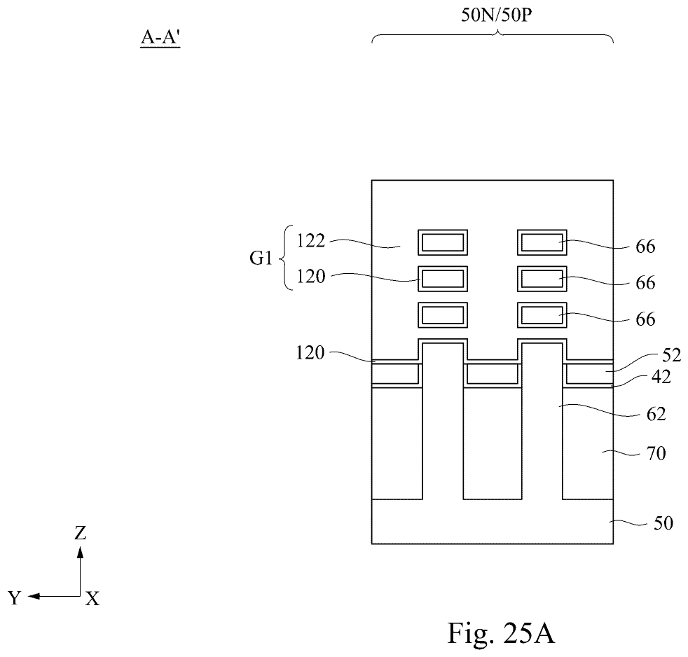

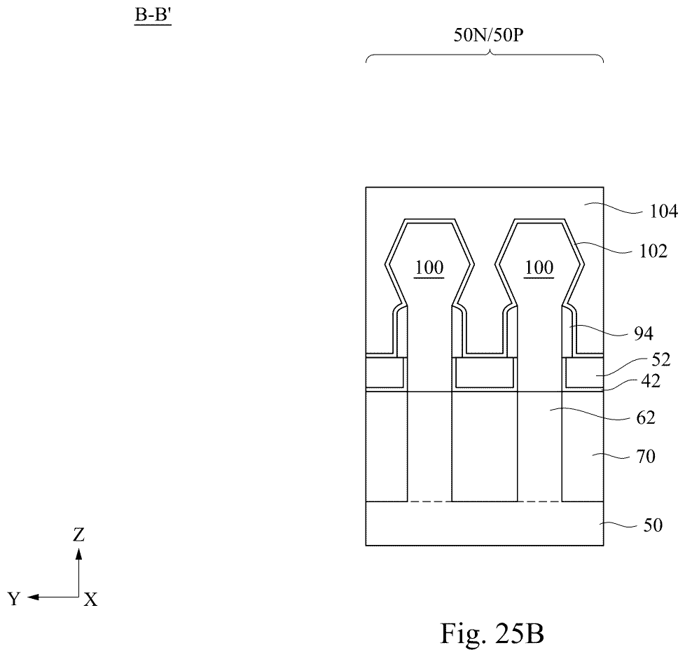

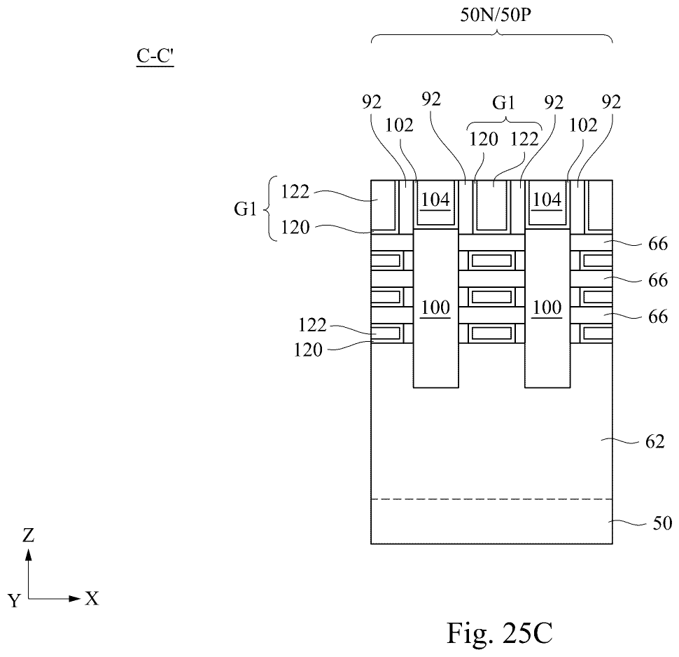

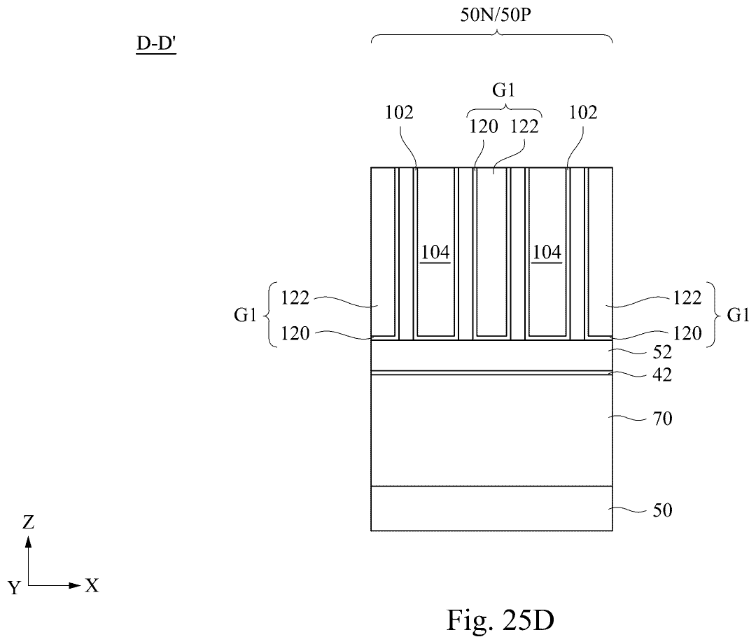

Reference is made to FIGS. 25A-25D. Gate dielectric layers 120 and gate electrodes 122 can be formed for replacement gate structures G1, in accordance with some embodiments. The gate dielectric layers 120 can be deposited conformally in the recesses 118. The gate dielectric layers 120 may be formed on top surfaces and sidewalls of the substrate 50 and on exposed top surfaces, sidewalls, and bottom surfaces of the nanostructures 66. The gate dielectric layers 120 may also be deposited on top surfaces of the ILD layer 104, the CESL 102, the gate spacers 92, and/or the STI regions 70.

In accordance with some embodiments, the gate dielectric layers 120 can comprise one or more dielectric layers, such as layer(s) of oxide, metal oxide, the like, or combinations thereof. For example, in some embodiments, the gate dielectric layers 120 may comprise a silicon oxide layer and a metal oxide layer over the silicon oxide layer. In some embodiments, the gate dielectric layers 120 can include a high-k dielectric material, and in these embodiments, the gate dielectric layers 120 may have a k value greater than about 7.0, and may include a metal oxide or a silicate of hafnium, aluminum, zirconium, lanthanum, manganese, barium, titanium, lead, and combinations thereof. The structure of the gate dielectric layers 120 may be the same or different in the first conductivity type device region 50N and the second conductivity type device region 50P. The formation methods of the gate dielectric layers 120 may include molecular-beam deposition (MBD), ALD, PECVD, and the like.

The gate electrodes 122 can be deposited over the gate dielectric layers 120, respectively, and fill the remaining portions of the recesses 118. The gate electrodes 122 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 122 are illustrated in FIGS. 25A, 25C, and 25D, the gate electrodes 122 may comprise any number of liner layers, any number of work function tuning layers, and a fill material. Any combination of the layers which make up the gate electrodes 122 may be deposited over surfaces of the nanostructures 66.

The formation of the gate dielectric layers 120 in the first conductivity type device region 50N and the second conductivity type device region 50P may occur simultaneously such that the gate dielectric layers 120 in each region can be formed from the same materials, and the formation of the gate electrodes 122 may occur simultaneously such that the gate electrodes 122 in each region are formed from the same materials. In some embodiments, the gate dielectric layers 120 in each region may be formed by distinct processes, such that the gate dielectric layers 120 may be different materials and/or have a different number of layers, and/or the gate electrodes 122 in each region may be formed by distinct processes, such that the gate electrodes 122 may be different materials and/or have a different number of layers. Various masking steps may be used to mask and expose appropriate regions when using distinct processes.

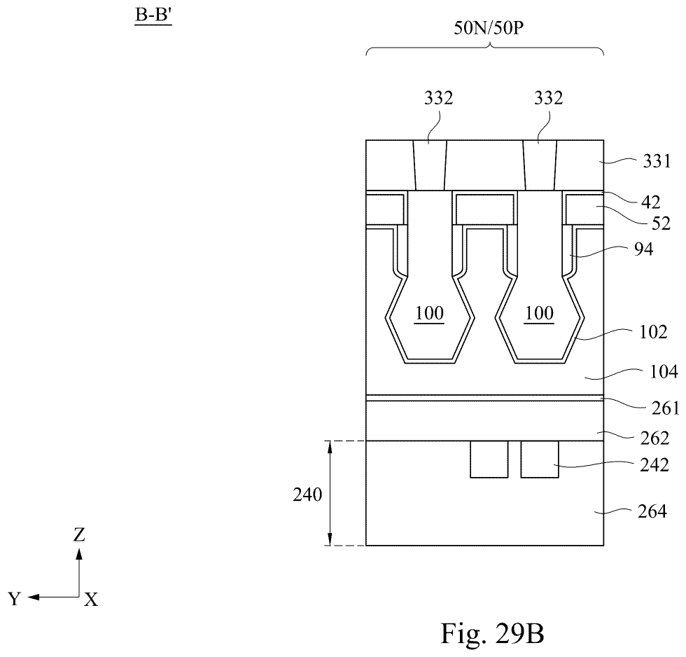

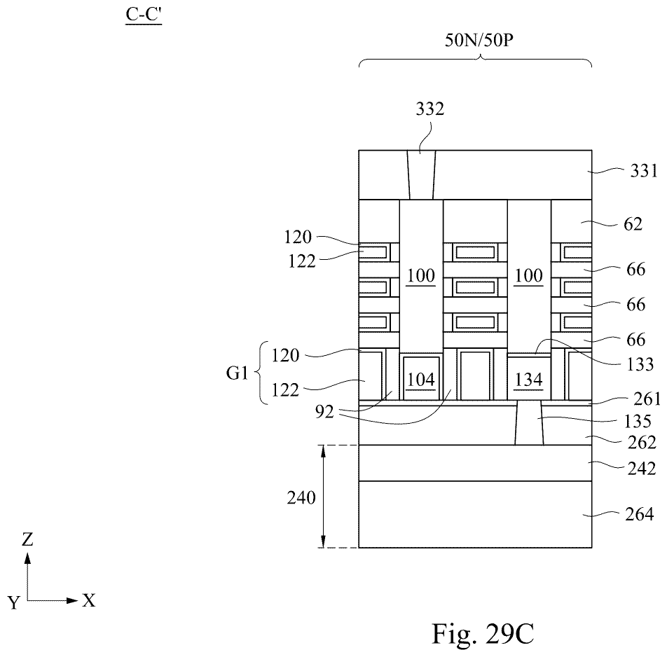

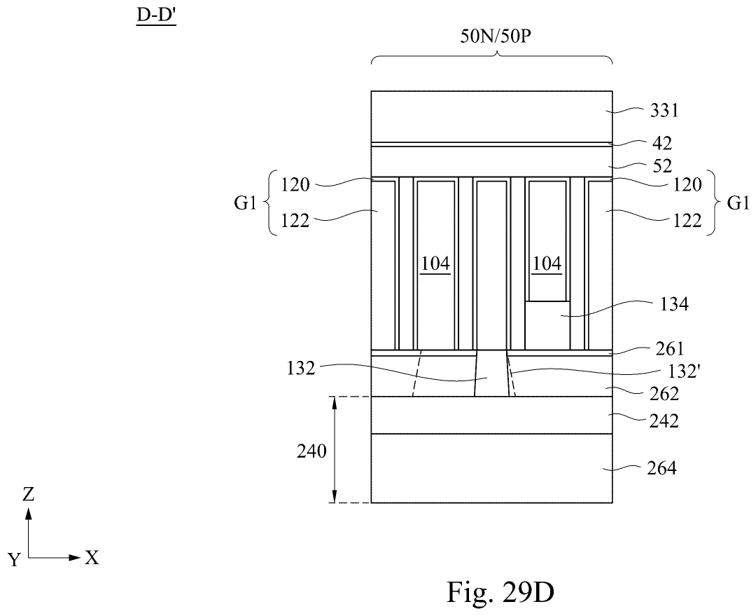

After the filling of the recesses 118, a planarization process, such as a CMP process, may be performed to remove the excess portions of the gate dielectric layers 120 and the material of the gate electrodes 122, which excess portions are over the top surface of the ILD layer 104. The remaining portions of material of the gate electrodes 122 and the gate dielectric layers 120 thus can form replacement gate structures G1 of the resulting nanostructure-FETs. The gate electrodes 122 and the gate dielectric layers 120 may be collectively referred to as gate structures or gate stacks. The gate isolation regions 116 separate and isolate regions of the gate structures G1, as shown in FIG. 29A.

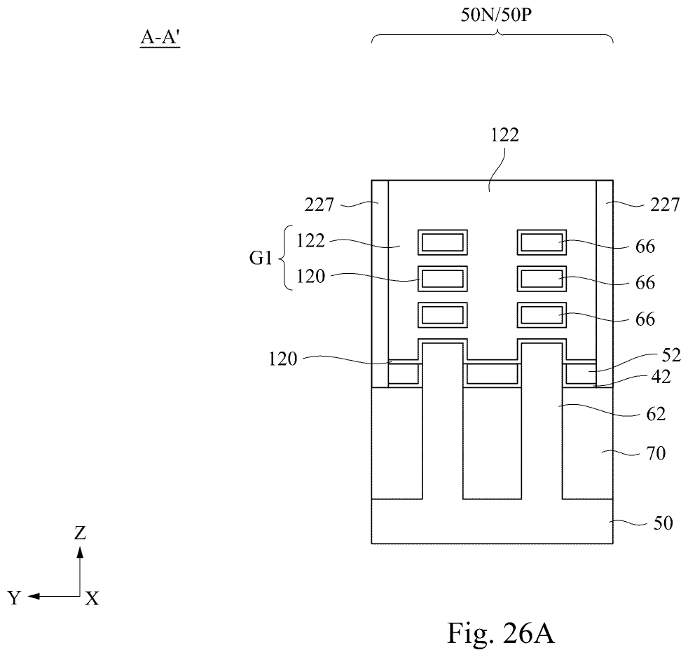

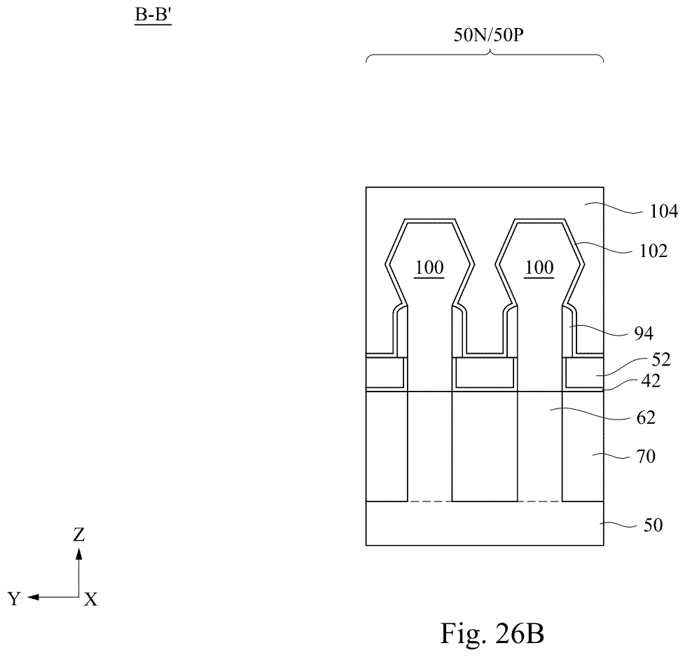

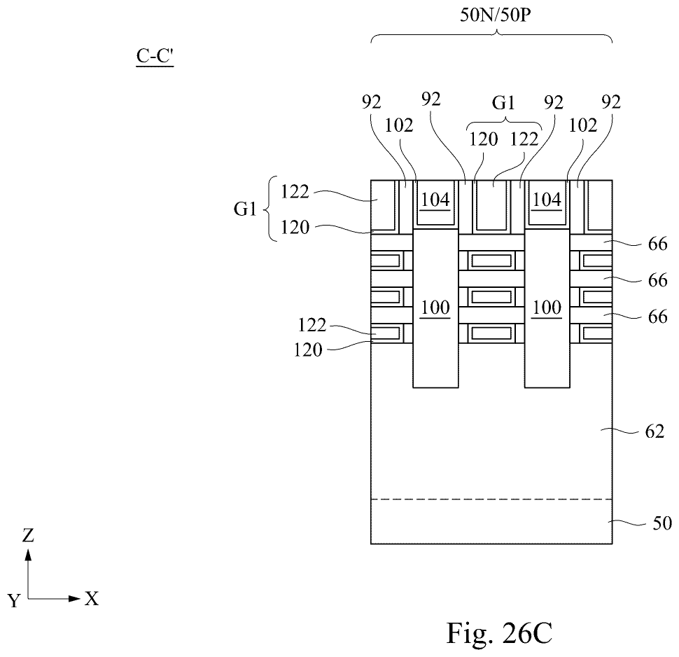

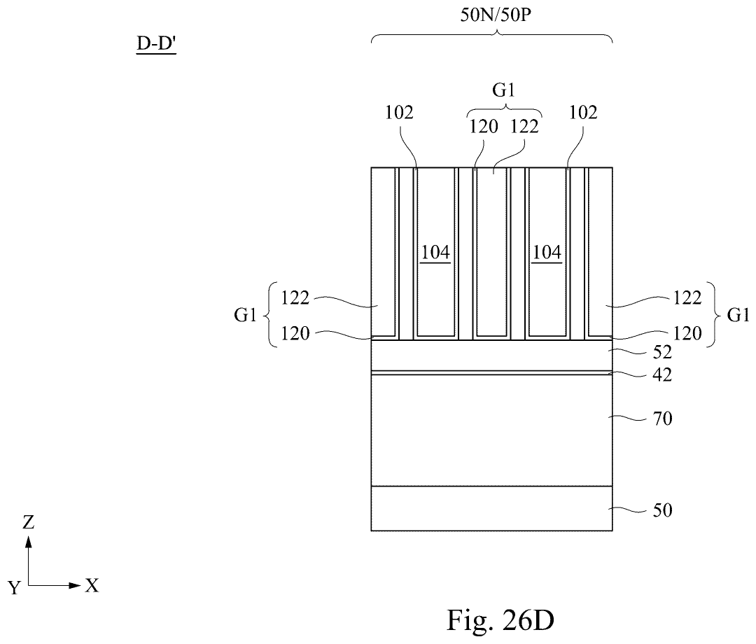

Reference is made to FIGS. 26A-26D. Dielectric regions 227 (see FIGS. 1A and 26A) can be formed on opposite ends of the gate structure G1. In some embodiments, each dielectric region 227 can be a gate-cut structure for the gate structure G1, and the gate-cut structure is formed by a cut metal gate (CMG) process. In some embodiments, the dielectric region 227 can be interchangeably referred to a gate end dielectric. Specifically, the opposite ends the gate structure G1 can be removed to form gate trenches. The ends of the gate structure G1 may be removed by dry etching, wet etching, or a combination of dry and wet etching. Subsequently, a dielectric material is deposited into the gate trenches, followed by a planarization process to remove excess portions of the dielectric material. The remaining dielectric material forms the dielectric regions 227.

In some embodiments, the deposition of the dielectric material of the dielectric regions 227 can be performed using a conformal deposition process such as ALD, which may be PEALD, thermal ALD, or the like. The dielectric material may be formed of or comprise SiO2, SiOC, SiOCN, or the like, or combinations thereof. In some embodiments, the dielectric region 227 may be made of a nitride-based material, such as Si3N4, or a carbon-based material, such as SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. The dielectric regions 227 may include dielectric liners, which may be formed of, for example, silicon oxide. In some embodiments, the dielectric material of the dielectric regions 227 comprises SiN, and the deposition is performed using process gases including dichlorosilane and ammonia. Hydrogen (H₂) may or may not be added.

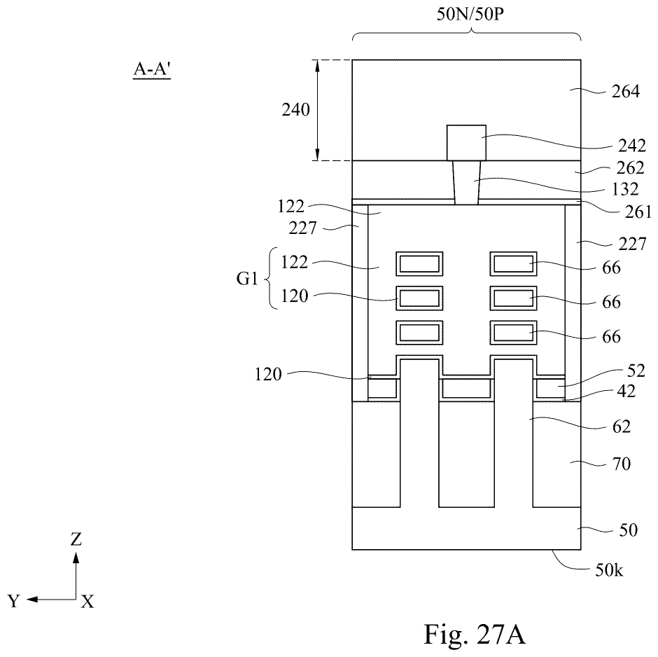

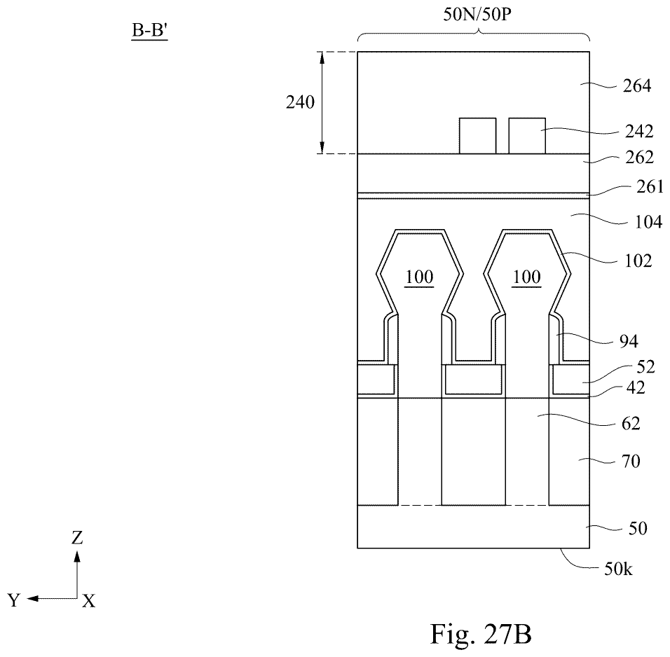

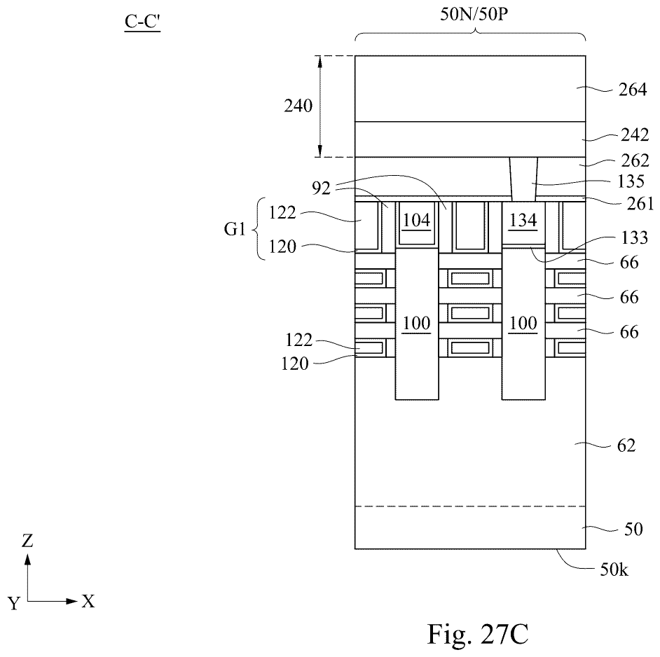

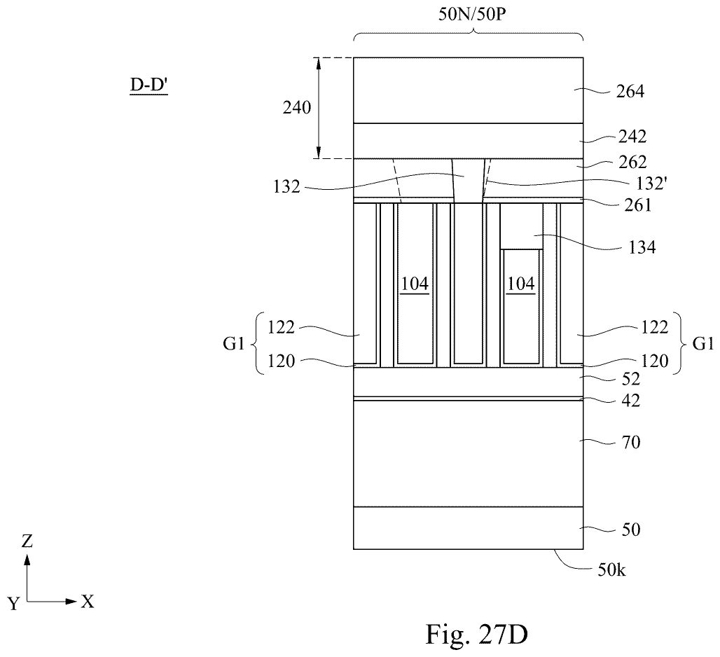

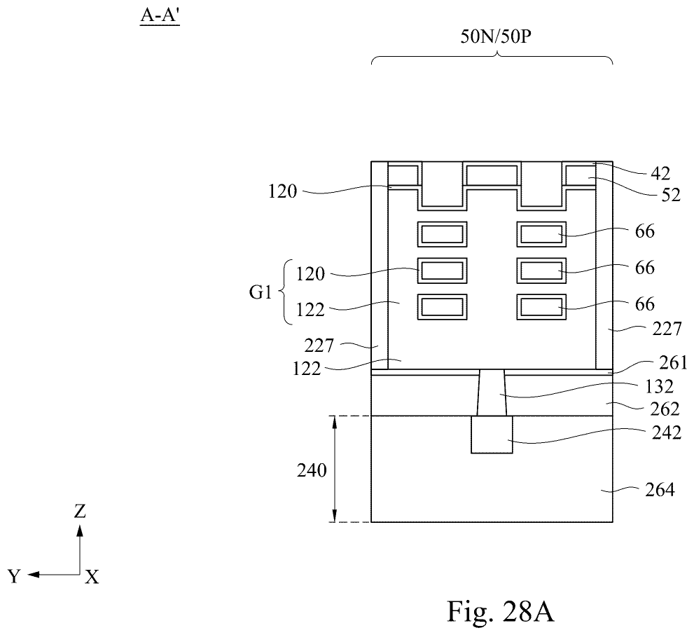

Reference is made to FIGS. 27A-27D. Source/drain contacts 134 (see FIGS. 27C and 27D) can be formed in the CESL 102 and the ILD layer 104 and over the epitaxial source/drain regions 100 by, such as cut metal-like defined region (CMD) process. The CMD process can be a method to define and shape a CMD region 137 as shown in FIGS. 1A and 1B (e.g., a dielectric region including the CESL 102 and the ILD layer 104 between adjacent source/drain contacts 134) and the regions for metal interconnections (i.e., source/drain contacts 134) in the integrated circuits. That is, the CMD region 137 as shown in FIGS. 1A and 1B can be formed by the CMD process to isolate the metal contacts (e.g., adjacent source/drain contacts 134) over the source/drain regions 100 for different N/P signal delivery. Specifically, the CMD process can include defining the CMD regions using photolithography, where a mask is used to pattern the regions on the dielectric material (e.g., ILD layer 104) that needs to be cut or shaped. After the CMD areas are defined, an etching process can remove the unwanted dielectric material, thereby shaping the dielectric isolation around the metal contacts.

Following the shaping of dielectric isolation through the CMD process, the exposed areas within the defined regions can be prepared for metal deposition. A metal such as Cu, Co, Ru, Pt, Al, W, Ti, TaN, TiN, molybdenum (Mo), ruthenium (Ru), iridium (Ir), rhodium (Rh), or any combinations thereof, known for good conductivity, can be deposited over the semiconductor structure. This metal can fill the trenches and other features etched into the dielectric material (e.g., the CESL 102 and the ILD layer 104) during the CMD process. The deposition can be performed using chemical vapor deposition (CVD), physical vapor deposition (PVD), or electrochemical plating, depending on the material and desired properties of the source/drain contacts 134. Once the metal is deposited, a removal process, such as chemical mechanical planarization (CMP) can be employed on the deposited metal. The result of the CMP process can be a series of metal-filled trenches that form the source/drain contacts 134.

In some embodiments, a front-side silicide layer 133 (see FIG. 27C) can be formed between the source/drain contact 134 and the epitaxial source/drain region 100. In some embodiments, a metal silicidation process can be performed on the epitaxial source/drain region 100 to form the front-side silicide layer 133. The metal silicidation process is to make a reaction between metal and silicon (or polycrystalline silicon). In some embodiments, a metal layer can be formed on the epitaxial source/drain region 100. Subsequently, regarding the metal silicidation process, a first rapid thermal annealing (RTA) process may be performed in, for example, Ar, He, N₂ or other inert atmosphere at a first temperature, such as lower than 200˜300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the front-side silicide layer 133 with low resistance. In some embodiments, the front-side silicide layer 133 may include titanium silicide (TiSi), nickel silicide (NiSi), cobalt silicide (CoSi), Ni—Pt, or combinations thereof.

Subsequently, an ILD layer 262 can be deposited over the CESL 102 and the ILD layer 104, and a contact etch stop layer (CESL) 261 can be formed between the ILD 262 and the ILD layer 104. Subsequently, metal via 135 (see FIG. 27C) can be formed in the ILD layer 262 and land on the source/drain contact 134. A gate via 132 (see FIGS. 27A and 27D) can be formed to pass through the ILD layer 262 and land on the gate structure G1. The metal via 135 and/or the gate via 132 may include a metal-containing material such as titanium nitride, titanium oxide, tungsten, cobalt, ruthenium, aluminum, copper, combinations thereof, multi-layers thereof, or the like. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. The CESL 261 may be formed of a dielectric material having a high etching selectivity from the etching of the ILD layer 262, such as silicon nitride, silicon oxide, silicon oxynitride, a combination thereof, or the like, which may be formed using any suitable deposition process, such as CVD, ALD, or the like.

Subsequently, a front-side interconnect structure 240 can be formed over the front-side gate via 132 and metal vias 135. The front-side interconnect structure 240 can include a plurality of metallization layers with a plurality of metallization vias or interconnects. Other embodiments may contain more or fewer metallization layers and corresponding more or fewer number of vias. The front-side interconnect structure 240 may include front-side inter-metal dielectric (IMD) layer 264 and at least one front-side metallization layer 242 formed in the IMD layer 264. In some embodiments, materials of the front-side metallization layer 242 may include Cu, Co, Ru, Pt, Al, W, Ti, TaN, TiN, molybdenum (Mo), ruthenium (Ru), iridium (Ir), rhodium (Rh), or any combinations thereof. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. Subsequently, a protection layer (not shown) can be formed over the front-side interconnect structure 240. The protection layer can be a single layer, some embodiments may utilize multiple dielectric layers. In some embodiments, the protection layer can be a poly layer, or a silicon substrate.

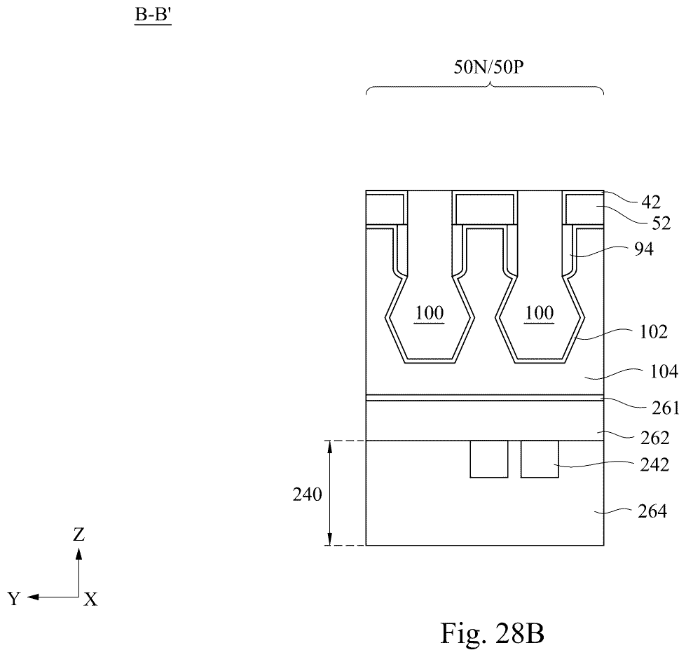

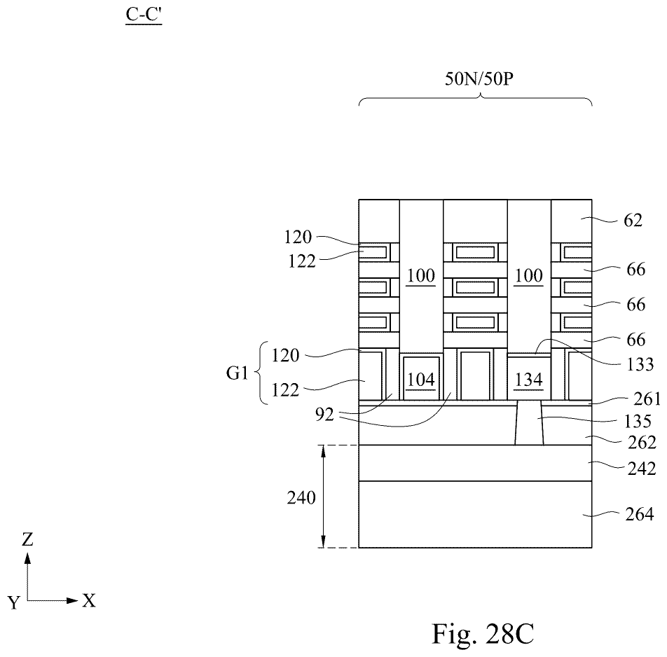

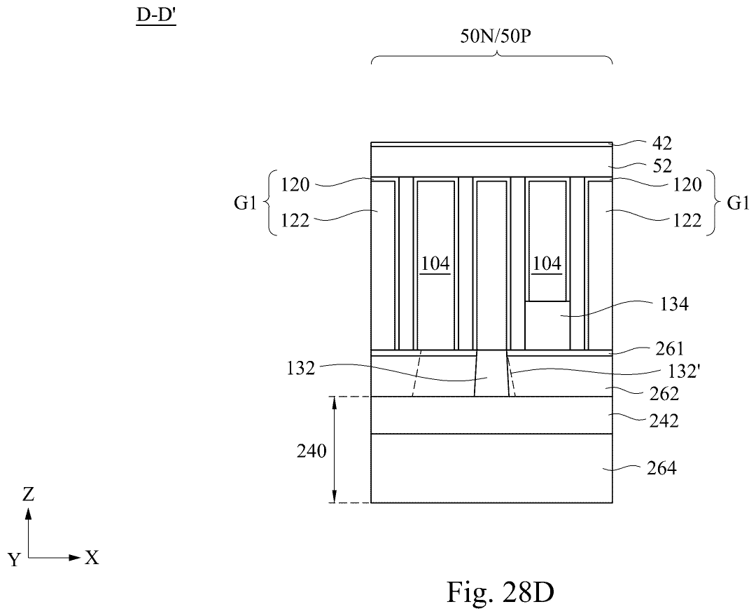

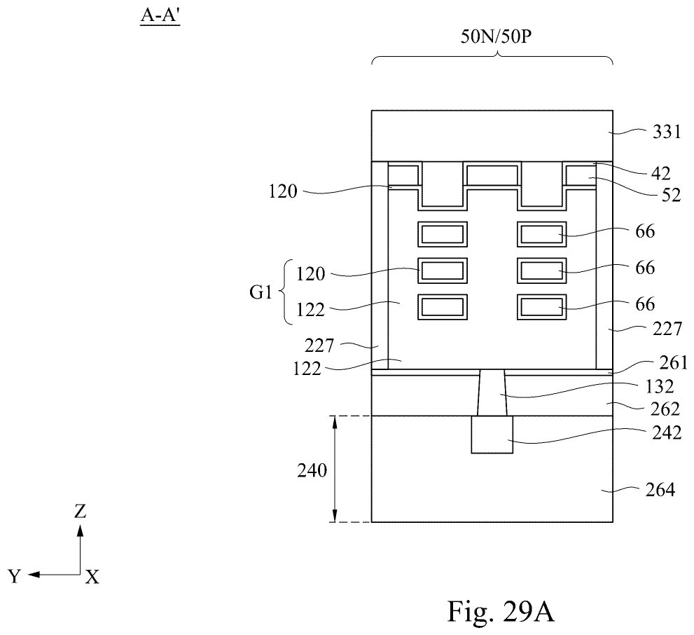

Reference is made to FIGS. 28A-28D. The structures of FIGS. 27A-27D can be “flipped” upside down, and the substrate 50 is removed. The substrate 50 may be removed in a plurality of process operations, for example, CMP, HNA, and/or TMAH etching from the back-side 50k (see FIGS. 27A-27D) of the substrate 50, which stops at the STI structure 251 or the fins 52. After the removal process, dielectric liner 42, the hard mask 52, the STI region, and/or the fins 62 can be exposed as shown in FIGS. 27A-27D.

Reference is made to FIGS. 29A-29D. A back-side dielectric layer 331 can be formed over a back-side of the semiconductor structure. In some embodiments, the back-side dielectric layer 331 may be made of dielectric material, such as SiO₂, Si₃N₄, SiON, SiOC, SiOCN base dielectric material, or combinations thereof. In some embodiments, the back-side dielectric layer 331 may be made of an oxide, a nitride-based material, such as Si₃N₄, SiON, or a carbon-based material, such as SiC, SiOC, SiOCN, or combinations thereof. In some embodiments, the back-side dielectric layer 331 may be made of a material having a dielectric constant greater than about 9 (e.g., high dielectric constant (high-k) material). For example, the back-side dielectric layer 331 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

Back-side contacts (e.g., power supply voltage contacts 332) can be formed in the back-side dielectric layer 331 and over the epitaxial source/drain regions 100. In some embodiments, materials of the back-side contacts may include Cu, Co, Ru, Pt, Al, W, Ti, TaN, TiN, Molybdenum (Mo), Ruthenium (Ru), Iridium (Ir), rhodium (Rh), or any combinations thereof.

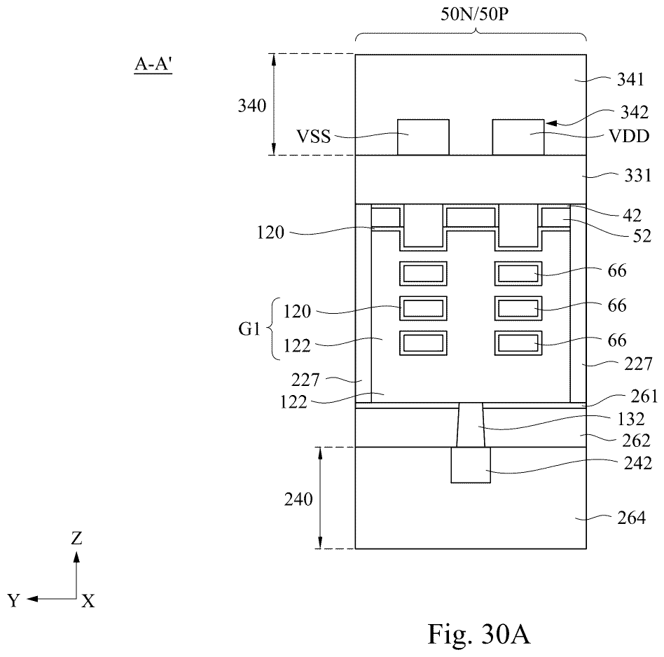

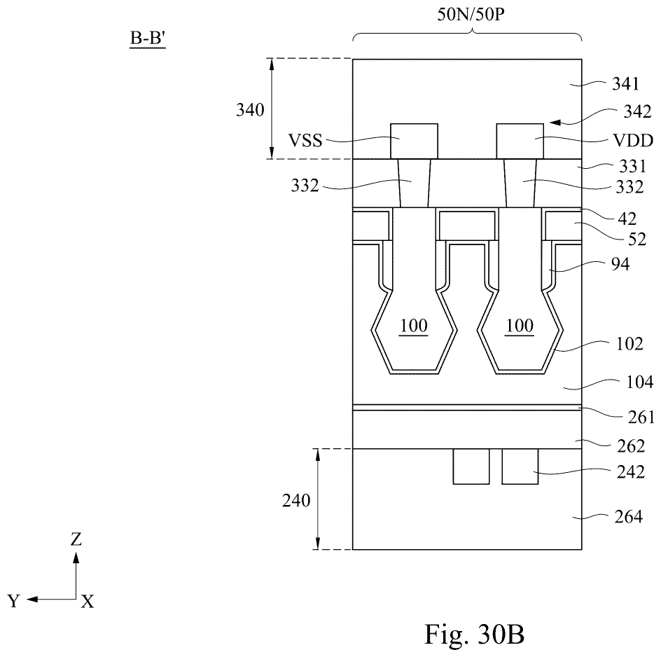

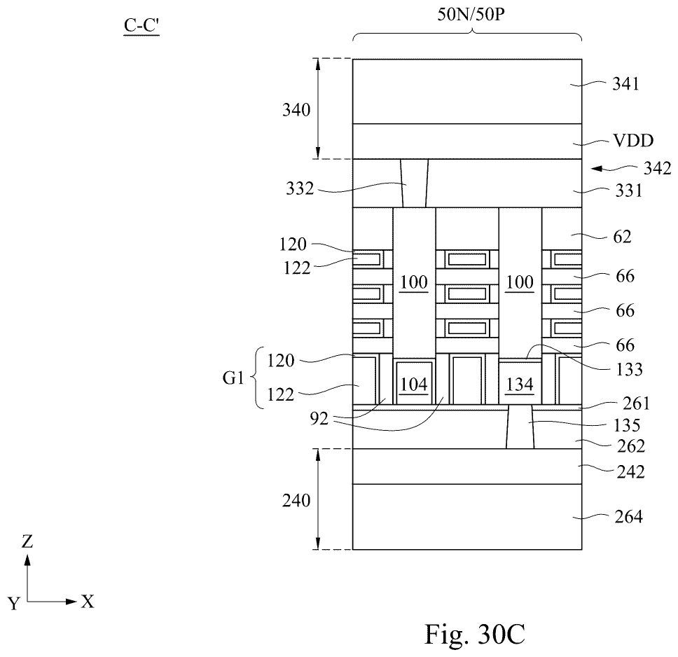

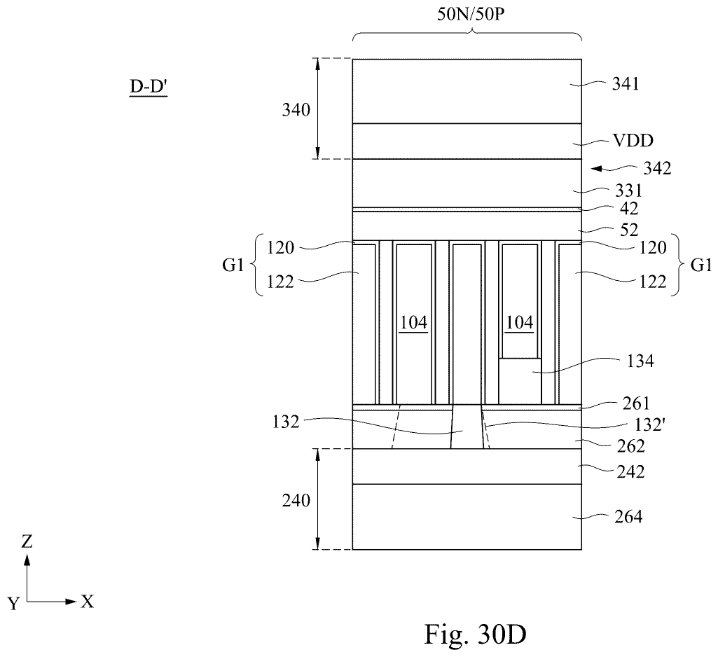

Reference is made to FIGS. 30A-30D. A back-side interconnect structure 340 can be formed over the back-side dielectric layer 331. The back-side interconnect structure 340 can include a back-side IMD layer 341 and a plurality of metallization layers 342 with a plurality of metallization vias or interconnects formed in the back-side IMD layer 341. Other embodiments may contain more or fewer metallization layers and corresponding more or fewer number of vias. The metallization layers 342 may include the power supply voltage lines VSS and VDD. In some embodiments, materials of the metallization layers 342 may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 341 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, after the forming of the back-side interconnect structure 340, a backside to front side connection module formation can be formed on the IC structure, such as a tap structure formation. Subsequently, backside bump pads formation and passivation layer formation can be formed on the back-side interconnect structure 340.

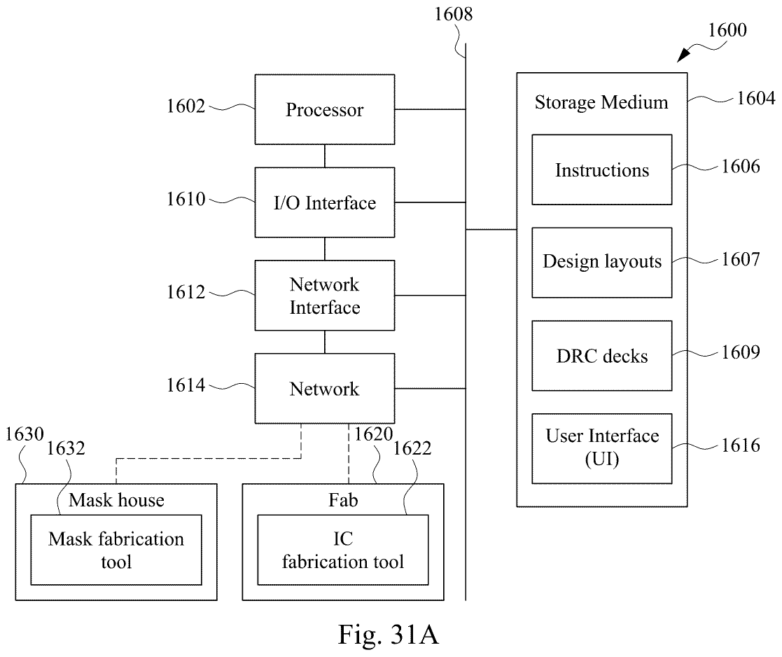

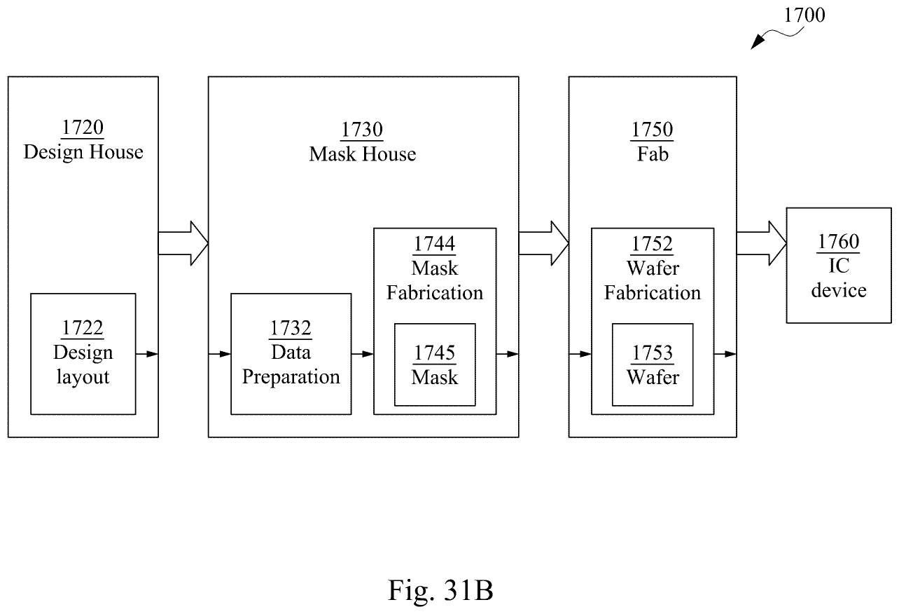

Reference is made to FIG. 31A. FIG. 31A is a schematic diagram of an electronic design automation (EDA) system 1600, in accordance with some embodiments. Methods described herein of generating design layouts, e.g., layouts of the integrated circuits of the semiconductor structure as discussed above, in accordance with one or more embodiments, are implementable, for example, using EDA system 1600, in accordance with some embodiments. At least integrated circuit is manufactured by a corresponding layout design similar to the corresponding integrated circuit. For brevity FIGS. 1A-30D are described as corresponding integrated circuits, but in some embodiments, FIGS. 1A-30D also correspond to layout designs with corresponding patterns with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the integrated circuits of the semiconductor structure as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 31A are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating integrated circuits of the semiconductor structure as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the integrated circuits of the semiconductor structure with resistor circuits as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a load lock chamber installed at a different wall face of the transfer chamber.

Reference is made to FIG. 31B. FIG. 31B is a block diagram of an IC manufacturing system 1700, and an IC manufacturing flow associated therewith, in accordance with some embodiments. In some embodiments, based on one or more design layouts, e.g., layouts of the integrated circuits of the semiconductor structure as discussed above, one or more photomasks and one or more integrated circuits are fabricated using manufacturing system 1700.

In FIG. 31B, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the integrated circuits of the semiconductor structure as discussed above). Design layouts 1722 include various geometrical patterns designed for ICs 1760 (e.g., integrated circuits of the semiconductor structure as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the integrated circuit of the semiconductor structure as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 31B, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the integrated circuits of the semiconductor structure as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a metal line routing method to improve the functional density and operation performance on the IC structure. Specifically, at least a part of power supply voltage lines (Vdd/Vss) and power conductive contacts can be moved to wafer back-side, so as to reduce the routing loading and improve the circuit density in a same chip area, which in turn simplifies the overall layout and reduces parasitic interactions. With fewer front-side source/drain contacts involved, the cut metal-like defined region (CMD) process can be streamlined. Additionally, the removal of source/drain contacts linked to power delivery can simplify the CPO process, allowing for easier and more consistent patterning across different semiconductor devices. In some embodiments, the gate via can be enlarged while no source/drain contact nearby, allowing for the enlargement of the critical dimension thereof, and thus optimizing the performance of the gate and reducing its electrical resistance.

In some embodiments, a method includes forming a plurality of first semiconductor channel layers stacked in a vertical direction over a substrate; forming a first gate strip surrounding each of the first semiconductor channel layers; forming a plurality of first source/drain regions on either side of each of the first semiconductor channel layers; forming a front-side source/drain contact over a front-side of a first one of the first source/drain regions; forming a first back-side source/drain contact over a back-side of a second one of the first source/drain regions, wherein a front-side of the second one of the first source/drain regions is free of a metal contact; forming a signal line over the front-side source/drain contact; forming a power supply voltage line over the first back-side source/drain contact. In some embodiments, the method further includes forming a plurality of second semiconductor channel layers stacked in the vertical direction over the substrate, wherein the first gate strip extends to surround each of the second semiconductor channel layers; forming a plurality of second source/drain regions on either side of each of the second semiconductor channel layers, wherein from a top view, the front-side source/drain contact extends in parallel with a lengthwise direction of the first gate strip and over a first one of the second source/drain regions, and a front-side of a second one of the second source/drain regions is free of the metal contact. In some embodiments, the method further includes forming a second back-side source/drain contact over a back-side of the second one of the second source/drain regions. In some embodiments, from a top view, the front-side source/drain contact extends beyond edges of the first semiconductor channel layers by a distance greater than about 3 nm. In some embodiments, from a top view, in a lengthwise direction of the first gate strip, a distance between a longitudinal end of the front-side source/drain contact and the first semiconductor channel layers is greater than a distance between the longitudinal end of the front-side source/drain contact and a longitudinal end of the first gate strip. In some embodiments, the method further includes forming a source/drain via over the front-side source/drain contact, wherein from a top view, in a lengthwise direction of the first gate strip, the source/drain via is spaced apart form an edge of the front-side source/drain contact by a distance greater than about 4 nm. In some embodiments, the method further includes forming a source/drain via over the front-side source/drain contact; forming a gate via over the first gate strip, wherein from a top view, the gate via has a greater dimension than the source/drain via in a direction perpendicular to a lengthwise direction of the first gate strip. In some embodiments, the method further includes forming a gate spacer over a sidewall of the first gate strip; forming a gate via over the first gate strip, wherein from a top view, the gate via extends across the gate spacer. In some embodiments, the method further includes forming a gate via over the first gate strip, wherein from a top view, the gate via overlaps with the first semiconductor channel layers. In some embodiments, the method further includes forming a second gate strip surrounding each of the first semiconductor channel layers; forming a first dielectric region adjoined with a longitudinal end of the first gate strip; forming a second dielectric region adjoined with a longitudinal end of the first gate strip, wherein from a top view, a distance between the first dielectric region and the first semiconductor channel layers is substantially equal to a distance between the second dielectric region and the first semiconductor channel layers.

In some embodiments, a method includes forming a semiconductive nanostructure over a substrate; forming epitaxial structures on opposite sides of the semiconductive nanostructure; forming a gate wrapping around the semiconductive nanostructure; forming a back-side metal contact over a back-side of a first one of the epitaxial structures, wherein a front-side of the first one of the epitaxial structures is free of a metal contact; forming a gate via over a front-side of the gate, wherein from a top view, the gate via has a first dimension extending along a lengthwise direction of the gate, and a second dimension extending along a direction perpendicular to the lengthwise direction of the gate, and the second dimension is greater than the first dimension. In some embodiments, the second dimension is greater than twice of the first dimension. In some embodiments, from the top view, the gate has a first longitudinal side and a second longitudinal side between the first longitudinal side and the back-side metal contact, and the second dimension extends across the second longitudinal side of the gate. In some embodiments, the method further includes forming a front-side metal contact over a second one of the epitaxial structures. In some embodiments, the method further includes forming a metal via over the front-side metal contact, wherein from the top view, an area of a top surface of the gate via is greater than an area of a top surface of the metal via.

In some embodiments, a semiconductor structure includes a first transistor, a second transistor, a source/drain contact, and a gate via. The first transistor includes first nanostructures, a first gate structure surrounding each of the first nanostructures, first source/drain structures on either side of each of the first nanostructures. The second transistor is adjacent to the first transistor, and includes second nanostructures, a second gate structure surrounding each of the second nanostructures, and second source/drain structures on either side of each of the second nanostructures. The source/drain contact extends from a front-side of a first one of the first source/drain structures to a front-side of a first one of the second source/drain structures. The gate via is over a front-side of the first gate structure, wherein from a top view, the gate via has a longitudinal axis extending in a direction perpendicular to a lengthwise direction of the first gate structure. In some embodiments, front-sides of the first and second transistors are free of a power mesh. In some embodiments, from the top view, the gate via is asymmetric based on a longitudinal axis of the first gate structure. In some embodiments, the semiconductor structure further includes a first back-side contact and a first power supply voltage line. The first back-side contact is over a back-side of a second one of the first source/drain structures. The first power supply voltage line is over the first back-side contact. In some embodiments, the semiconductor structure further includes a second back-side contact and a second power supply voltage line. The second back-side contact is over a back-side of a second one of the second source/drain structures. The second power supply voltage line is over the second back-side contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of first semiconductor channel layers stacked in a vertical direction over a substrate;
forming a first gate strip surrounding each of the first semiconductor channel layers;
forming a plurality of first source/drain regions on either side of each of the first semiconductor channel layers;
forming a front-side source/drain contact over a front-side of a first one of the first source/drain regions;
forming a first back-side source/drain contact over a back-side of a second one of the first source/drain regions, wherein a front-side of the second one of the first source/drain regions is free of a metal contact;
forming a signal line over the front-side source/drain contact; and
forming a power supply voltage line over the first back-side source/drain contact.

2. The method of claim 1, further comprising:
forming a plurality of second semiconductor channel layers stacked in the vertical direction over the substrate, wherein the first gate strip extends to surround each of the second semiconductor channel layers; and
forming a plurality of second source/drain regions on either side of each of the second semiconductor channel layers, wherein from a top view, the front-side source/drain contact extends in parallel with a lengthwise direction of the first gate strip and over a first one of the second source/drain regions, and a front-side of a second one of the second source/drain regions is free of the metal contact.

3. The method of claim 2, further comprising:
forming a second back-side source/drain contact over a back-side of the second one of the second source/drain regions.

4. The method of claim 1, wherein from a top view, the front-side source/drain contact extends beyond edges of the first semiconductor channel layers by a distance greater than about 3 nm.

5. The method of claim 1, wherein from a top view, in a lengthwise direction of the first gate strip, a distance between a longitudinal end of the front-side source/drain contact and the first semiconductor channel layers is greater than a distance between the longitudinal end of the front-side source/drain contact and a longitudinal end of the first gate strip.

6. The method of claim 1, further comprising:
forming a source/drain via over the front-side source/drain contact, wherein from a top view, in a lengthwise direction of the first gate strip, the source/drain via is spaced apart form an edge of the front-side source/drain contact by a distance greater than about 4 nm.

7. The method of claim 1, further comprising:
forming a source/drain via over the front-side source/drain contact; and
forming a gate via over the first gate strip, wherein from a top view, the gate via has a greater dimension than the source/drain via in a direction perpendicular to a lengthwise direction of the first gate strip.

8. The method of claim 1, further comprising:
forming a gate spacer over a sidewall of the first gate strip; and
forming a gate via over the first gate strip, wherein from a top view, the gate via extends across the gate spacer.

9. The method of claim 1, further comprising:
forming a gate via over the first gate strip, wherein from a top view, the gate via overlaps with the first semiconductor channel layers.

10. The method of claim 1, further comprising:
forming a second gate strip surrounding each of the first semiconductor channel layers; forming a first dielectric region adjoined with a longitudinal end of the first gate strip; and
forming a second dielectric region adjoined with a longitudinal end of the first gate strip, wherein from a top view, a distance between the first dielectric region and the first semiconductor channel layers is substantially equal to a distance between the second dielectric region and the first semiconductor channel layers.

11. A method, comprising:
forming a semiconductive nanostructure over a substrate;
forming epitaxial structures on opposite sides of the semiconductive nanostructure;
forming a gate wrapping around the semiconductive nanostructure;
forming a back-side metal contact over a back-side of a first one of the epitaxial structures, wherein a front-side of the first one of the epitaxial structures is free of a metal contact; and
forming a gate via over a front-side of the gate, wherein from a top view, the gate via has a first dimension extending along a lengthwise direction of the gate, and a second dimension extending along a direction perpendicular to the lengthwise direction of the gate, and the second dimension is greater than the first dimension.

12. The method of claim 11, wherein the second dimension is greater than twice of the first dimension.

13. The method of claim 11, wherein from the top view, the gate has a first longitudinal side and a second longitudinal side between the first longitudinal side and the back-side metal contact, and the second dimension extends across the second longitudinal side of the gate.

14. The method of claim 11, further comprising:
forming a front-side metal contact over a second one of the epitaxial structures.

15. The method of claim 14, further comprising:
forming a metal via over the front-side metal contact, wherein from the top view, an area of a top surface of the gate via is greater than an area of a top surface of the metal via.

16. A semiconductor structure, comprising:
a first transistor, comprising:
first nanostructure;
a first gate structure surrounding each of the first nanostructures; and
a plurality of first source/drain structures on either side of each of the first nanostructures;
a second transistor adjacent to the first transistor, and comprising;
second nanostructures;
a second gate structure surrounding each of the second nanostructures; and
a plurality of second source/drain structures on either side of each of the second nanostructures;
a source/drain contact extending from a front-side of a first one of the first source/drain structures to a front-side of a first one of the second source/drain structures; and
a gate via over a front-side of the first gate structure, wherein from a top view, the gate via has a longitudinal axis extending in a direction perpendicular to a lengthwise direction of the first gate structure.

17. The semiconductor structure of claim 16, wherein front-sides of the first and second transistors are free of a power mesh.

18. The semiconductor structure of claim 16, wherein from the top view, the gate via is asymmetric based on a longitudinal axis of the first gate structure.

19. The semiconductor structure of claim 16, further comprising:
a first back-side contact over a back-side of a second one of the first source/drain structures; and
a first power supply voltage line over the first back-side contact.

20. The semiconductor structure of claim 19, further comprising:
a second back-side contact over a back-side of a second one of the second source/drain structures; and
a second power supply voltage line over the second back-side contact.
